(19) United States
(12) Patent Application Publication
(10) Pub. No.: US 2025/0318259 A1
(43) Pub. Date: Oct. 9, 2025

(54) INTEGRATED CIRCUIT DEVICE INCLUDING A FIN-SHAPED ACTIVE REGION

(71) Applicant: SAMSUNG ELECTRONICS CO., LTD., SUWON-SI (KR)

(72) Inventors: Dahye Kim, Suwon-si (KR); Jaehyun Park, Suwon-si (KR); Jinchan Yun, Suwon-si (KR); Daihong Huh, Suwon-si (KR)

(21) Appl. No.: 19/005,182

(22) Filed: Dec. 30, 2024

(30) Foreign Application Priority Data
Apr. 5, 2024 (KR) 10-2024-0046957

(51) Int. Cl. H10D 84/83; H10D 62/60; H10D 84/01; H10D 84/85

(52) U.S. Cl. CPC H10D 84/8312; H10D 62/60; H10D 84/013; H10D 84/832; H10D 84/856

(57) ABSTRACT

An integrated circuit device includes a fin-shaped active region. A pair of lower channel regions are disposed on the active region. A pair of upper channel regions are disposed on upper portions of the lower channel regions. A lower source/drain region is formed on the active region, contacting the pair of lower channel regions. An upper source/drain region is formed on the lower source/drain region, contacting the pair of upper channel regions. The upper source/drain region includes a first semiconductor pattern contacting side surfaces of the pair of upper channel regions, a second semiconductor pattern covering the first semiconductor pattern, and a third semiconductor pattern filled between the pair of upper gate portions, and covering the first semiconductor pattern and the second semiconductor pattern. A lowermost portion of a lower surface of the upper source/drain region is a part of a lower surface of the third semiconductor pattern.

### CROSS-REFERENCE TO RELATED APPLICATION

This application claims priority under 35 U.S.C. § 119 to Korean Patent Application No. 10-2024-0046957, filed on Apr. 5, 2024, in the Korean Intellectual Property Office, the disclosure of which is incorporated by reference herein in its entirety.

### TECHNICAL FIELD

The inventive concept relates to integrated circuit devices and, more particularly, to an integrated circuit device including a fin-shaped active region.

### DISCUSSION OF THE RELATED ART

Modern electronic devices are becoming smaller, offer multiple functions, an provide high performance. Achieving these advances has led to an increase in the degree of capacity and integration of integrated circuits (“ICs”). As ICs have become more highly integrated, the wiring structures needed to connect them to the electronic devices have also become more complicated.

### SUMMARY

An integrated circuit device includes a fin-shaped active region extending in a first horizontal direction on a substrate. On the fin-shaped active region, a pair of lower channel regions are spaced apart from one another in the first horizontal direction. On upper portions of the pair of lower channel regions, a pair of upper channel regions are spaced apart from one another in the first horizontal direction. On the fin-shaped active region, a gate line includes a pair of lower gate portions surrounding the pair of lower channel regions and extending in a second horizontal direction intersecting the first horizontal direction. A pair of upper gate portions surrounds the pair of upper channel regions and extends in the second horizontal direction. On the fin-shaped active region, a lower source/drain region is adjacent to the pair of lower gate portions, and contacts the pair of lower channel regions. On the lower source/drain region, an upper source/drain region is adjacent to the pair of upper gate portions, and contacts the pair of upper channel regions. An isolation structure is disposed between the lower source/drain region and the upper source/drain region. The upper source/drain region includes a first semiconductor pattern contacting side surfaces of the pair of upper channel regions, a second semiconductor pattern covering the first semiconductor pattern, and a third semiconductor pattern filled between the pair of upper gate portions, and covering the first semiconductor pattern and the second semiconductor pattern. A lowermost portion of a lower surface of the upper source/drain region is a part of a lower surface of the third semiconductor pattern.

An integrated circuit device includes a fin-shaped active region extending in a first horizontal direction on a substrate. A lower stack includes a lower source/drain region disposed on the fin-shaped active region. On an upper portion of the lower stack, an upper stack includes an upper nanosheet stack including a plurality of upper nanosheets stacked in a vertical direction. An upper gate portion is disposed between each of the plurality of upper nanosheets and extends in a second horizontal direction intersecting the first horizontal direction. An upper source/drain region is adjacent to the upper gate portion and contacts the plurality of upper nanosheets. An isolation structure contacts each of the lower source/drain region and the upper source/drain region, between the lower stack and the upper stack. The upper source/drain region includes a first semiconductor pattern contacting side surfaces of the plurality of upper nanosheets, and a second semiconductor pattern covering the first semiconductor pattern. An uppermost portion of a lower surface of the upper source/drain region is a part of a lower surface of the second semiconductor pattern.

An integrated circuit device includes a fin-shaped active region extending in a first horizontal direction on a substrate. A lower stack is disposed on the fin-shaped active region. An isolation structure is disposed on the lower stack. An upper stack is disposed on the isolation structure. The lower stack includes, on the fin-shaped active region, a pair of lower channel regions spaced apart from one another in the first horizontal direction. A pair of lower gate portions respectively surround the pair of lower channel regions and extend in a second horizontal direction intersecting the first horizontal direction. A lower source/drain region is adjacent to the pair of lower gate portions, is disposed between the pair of lower channel regions, and contacts the pair of lower channel regions. The upper stack includes a pair of upper channel regions spaced apart from one another in the first horizontal direction, a pair of upper gate portions respectively surrounding the pair of upper channel regions and extending in the second horizontal direction, and an upper source/drain region adjacent to the pair of upper gate portions, disposed between the pair of upper channel regions, and contacting the pair of upper channel regions. The isolation structure contacts the lower source/drain region and the upper source/drain region. The upper source/drain region includes a first semiconductor pattern contacting side surfaces of the pair of upper channel regions, a second semiconductor pattern covering the first semiconductor pattern, and third semiconductor pattern filled between the pair of upper channel regions, and covering the first semiconductor pattern and the second semiconductor pattern. The third semiconductor pattern contacts the isolation structure. At least a part of a lower surface of the upper source/drain region is a part of a lower surface of the third semiconductor pattern. The lower stack is a p-channel metal-oxide-semiconductor (PMOS) device, and the upper stack is an n-channel metal-oxide-semiconductor (NMOS) device.

### BRIEF DESCRIPTION OF THE DRAWINGS

Embodiments will be more clearly understood from the following detailed description taken in conjunction with the accompanying drawings in which:

FIG. 1 is a plan layout diagram illustrating an integrated circuit device according to some embodiments;

FIG. 2 is a cross-sectional view illustrating an integrated circuit device according to some embodiments;

FIGS. 3 and 4 are enlarged cross-sectional views of a region EX1 and a region EX2 of FIG. 2, respectively;

FIGS. 5 and 6 are enlarged cross-sectional views illustrating integrated circuit devices according to some embodiments;

FIG. 7 is a cross-sectional view illustrating an integrated circuit device according to some embodiments;

FIG. 8 is an enlarged cross-sectional view of a region EX3 of FIG. 7;

FIG. 9 is an enlarged cross-sectional view illustrating an integrated circuit device according to some embodiments;

FIG. 10 is a cross-sectional view illustrating an integrated circuit device according to some embodiments;

FIG. 11 is an enlarged cross-sectional view of a region EX4 of FIG. 10;

FIG. 12 is an enlarged cross-sectional view illustrating an integrated circuit device according to some embodiments;

FIG. 13 is a cross-sectional view illustrating an integrated circuit device according to some embodiments;

FIG. 14 is an enlarged cross-sectional view of a region EX5 of FIG. 13;

FIG. 15 is an enlarged cross-sectional view illustrating an integrated circuit device according to embodiments of the technical idea of the inventive concept;

FIG. 16 is a cross-sectional view illustrating an integrated circuit device according to some embodiments;

FIG. 17 is an enlarged cross-sectional view of a region EX6 of FIG. 16;

FIG. 18 is an enlarged cross-sectional view illustrating an integrated circuit device according to embodiments of the technical idea of the inventive concept;

FIGS. 19A to 19M are cross-sectional views illustrating a method of manufacturing an integrated circuit device according to some embodiments based on a process sequence;

FIGS. 20A and 20B are intermediate cross-sectional views illustrating a method of manufacturing an integrated circuit device according to some embodiments based on a process sequence; and

FIGS. 21A to 21C are intermediate cross-sectional views illustrating a method of manufacturing an integrated circuit device according to some embodiments based on a process sequence.

### DETAILED DESCRIPTION OF THE EMBODIMENTS

Hereinafter, embodiments of the inventive concept will be described in detail with reference to the accompanying drawings. The same reference numerals may be used for the same components in the drawings and the description, and to the extent that an element is not described in detail with respect to this figure, it may be understood that the element is at least similar to a corresponding element that has been described elsewhere within the present disclosure.

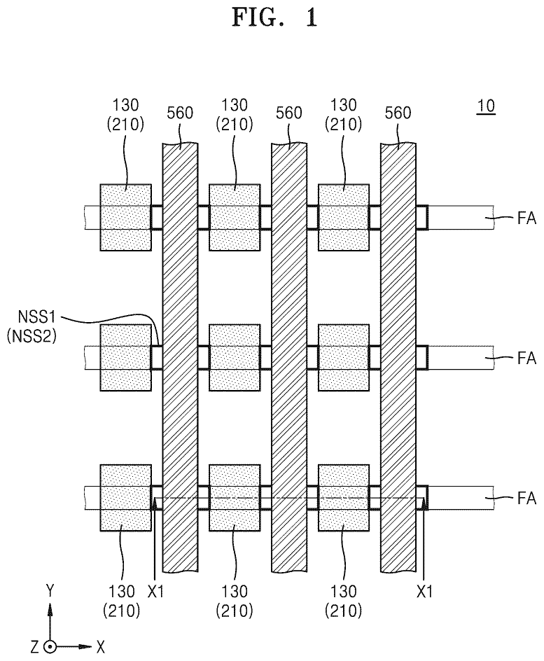

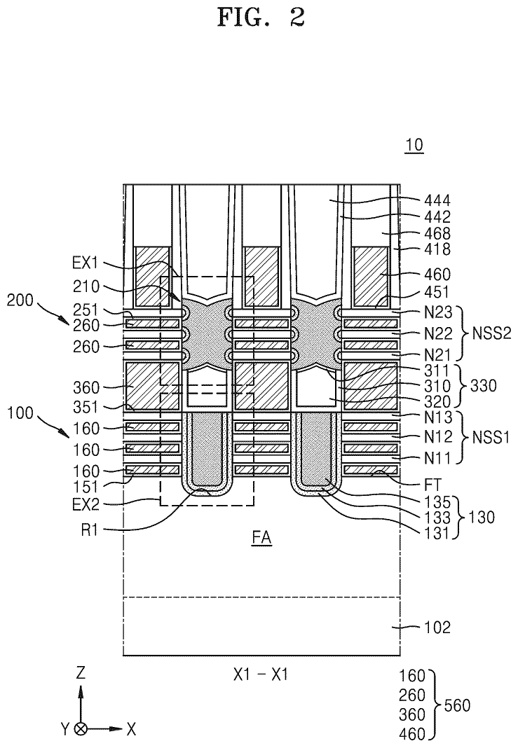

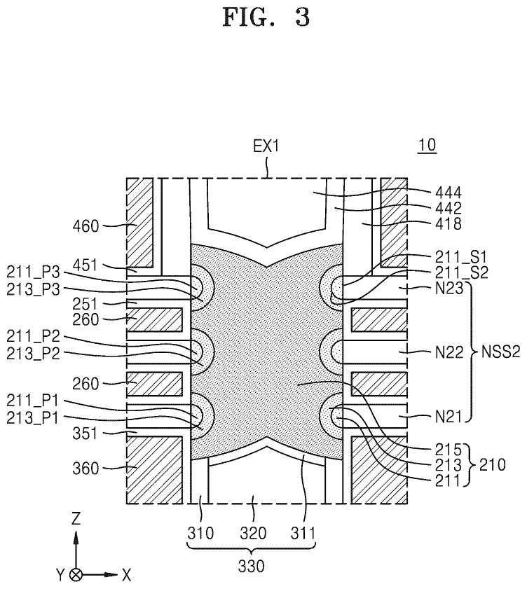

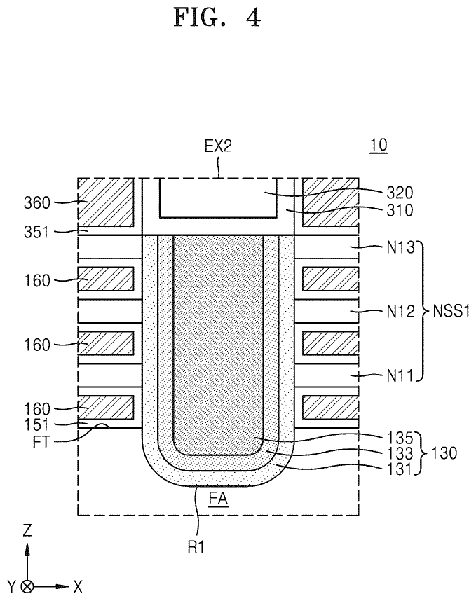

FIG. 1 is a plan layout diagram illustrating an integrated circuit device 10 according to some embodiments. FIG. 2 is a cross-sectional view illustrating the integrated circuit device 10 according to some embodiments. For example, FIG. 2 is a cross-sectional view taken along line X1-X1 of FIG. 1. FIGS. 3 and 4 are enlarged cross-sectional views of a region EX1 and a region EX2 of FIG. 2, respectively.

Hereinafter, the integrated circuit device 10 including active regions FA each in the shape of a nanowire or a nanosheet, a field effect transistor having a gate-all-around structure including a gate surrounding the active regions FA, and a lower stack 100 and an upper stack 200 stacked in a vertical direction (e.g., Z direction) will be described with reference to FIGS. 1 to 4.

The integrated circuit device 10 may include a substrate 102 and the plurality of fin-shaped active regions FA protruding from the substrate 102. The plurality of fin-shaped active regions FA may extend primarily in a first horizontal direction (e.g., X direction) parallel to each other on the substrate 102.

The substrate 102 may include a semiconductor such as Si or Ge, or a compound semiconductor such as SiGe, SiC, GaAs, InAs, InGaAs, or InP. As used herein, the terms “SiGe”, “SiC”, “GaAs”, “InAs”, “InGaAs”, and “InP” mean materials including elements included in the terms, and are not necessarily chemical equations exhibiting a stoichiometric relationship. The substrate 102 may include a conductive region, for example, a well doped with an impurity, or a structure doped with an impurity.

The plurality of fin-type active regions FA may be limited by a device isolation layer. The device isolation layer may include a silicon oxide layer. The device isolation layer may include a material with a different etch selectivity from that of the substrate 102.

As illustrated in FIGS. 1 and 2, a plurality of gate lines 560 may be disposed on the plurality of fin-type active regions FA. Each of the plurality of gate lines 560 may extend primarily in a second horizontal direction (e.g., Y direction) that intersects the first horizontal direction (e.g., X direction).

As illustrated in FIGS. 1 and 2, in regions where the plurality of fin-type active regions FA and the plurality of gate lines 560 intersect, a plurality of nanosheet stacks NSS1 and NSS2 may be disposed on an upper portion of a fin top surface FT of each of the plurality of fin-type active regions FA. The plurality of nanosheet stacks NSS1 and NSS2 may each include at least one nanosheet facing the fin top surface FT at a position spaced apart from the fin top surface FT of the fin-type active region FA in a vertical direction (e.g., Z direction). The plurality of gate lines 560 may respectively surround a plurality of nanosheets included in the plurality of nanosheet stacks NSS1 and NSS2. As used herein, the term “nanosheet” refers to a conductive structure having a cross section substantially perpendicular to a direction in which current flows. The nanosheet should be understood to include a nanowire.

In some embodiments, the plurality of nanosheet stacks NSS1 and NSS2 may include a plurality of lower nanosheet stacks NSS1 included in the lower stack 100 and a plurality of upper nanosheet stacks NSS2 included in the upper stack 200.

As illustrated in FIGS. 2 and 4, the plurality of lower nanosheet stacks NSS1 may each include a first lower nanosheet N11, a second lower nanosheet N12, and a third lower nanosheet N13 that overlap each other in the vertical direction (e.g., Z direction) on the fin-shaped active region FA. The first lower nanosheet N11, the second lower nanosheet N12, and the third lower nanosheet N13 have different vertical distances (e.g., in the Z direction) from the fin top surface FT of the fin-shaped active region FA.

As illustrated in FIGS. 2 and 3, the plurality of upper nanosheet stacks NSS2 may each include a first upper nanosheet N21, a second upper nanosheet N22, and a third upper nanosheet N23 that overlap each other in the vertical direction (e.g., Z direction) on the plurality of lower nanosheet stacks NSS1. The first upper nanosheet N21, the second upper nanosheet N22, and the third upper nanosheet N23 have different vertical distances (e.g., in the Z direction) from the fin top surface FT of the fin-shaped active region FA.

FIG. 2 shows that a planar shape of each of the lower and upper nanosheet stacks NSS1 and NSS2 is approximately rectangular, but the inventive concept is not necessarily limited thereto. The plurality of lower and upper nanosheet stacks NSS1 and NSS2 may have various planar shapes according to planar shapes of each of the fin-type active regions FA and the gate lines 560. In the example, the plurality of lower and upper nanosheet stacks NSS1 and NSS2 and the plurality of gate lines 560 are disposed on one fin-type active region FA, and the plurality of lower and upper nanosheet stacks NSS1 and NSS2 are disposed on one fin-type active region FA in a row in the first horizontal direction (e.g., X direction). However, the number of each of the lower and upper nanosheet stacks NSS1 and NSS2 and the gate lines 560 disposed on one fin-type active region FA is not necessarily particularly limited thereto.

A plurality of nanosheets included in the lower and upper nanosheet stacks NSS1 and NSS2 may each function as a channel region. For example, the first lower nanosheet N11, the second lower nanosheet N12, and the third lower nanosheet N13 included in the lower nanosheet stack NSS1 may each function as the channel region. Likewise, the first upper nanosheet N21, the second upper nanosheet N22, and the third upper nanosheet N23 included in the upper nanosheet stack NSS2 may each function as the channel region.

In some embodiments, the plurality of nanosheets may have substantially the same thickness in the vertical direction (e.g., Z direction). In some embodiments, at least some of the plurality of nanosheets may have different thicknesses in the vertical direction (e.g., Z direction). In some embodiments, the plurality of nanosheets included in the lower and upper nanosheet stacks NSS1 and NSS2 may each include a Si layer, a SiGe layer, or a combination thereof.

As illustrated in FIG. 2, the plurality of nanosheets included in one lower and upper nanosheet stack NSS1 and NSS2 may have the same or similar size to each other in the first horizontal direction (e.g., X direction). In some embodiments, unlike the example in FIG. 2, at least some of the plurality of nanosheets included in one lower and upper nanosheet stack NSS1 and NSS2 have different sizes in the first horizontal direction (e.g., X direction).

In the example, the plurality of lower and upper nanosheet stacks NSS1 and NSS2 each include three nanosheets, but the inventive concept is not necessarily limited to the example. For example, the lower and upper nanosheet stacks NSS1 and NSS2 may include at least one nanosheet, and the number of nanosheets constituting the lower and upper nanosheet stacks NSS1 and NSS2 is not necessarily particularly limited thereto.

As illustrated in FIG. 2, the plurality of gate lines 560 may respectively include a plurality of lower gate portions 160 and a plurality of upper gate portions 260.

In some embodiments, the plurality of lower gate portions 160 may each be disposed between each of the first lower nanosheet N11, the second lower nanosheet N12, and the third lower nanosheet N13 included in the lower nanosheet stack NSS1 and between the first lower nanosheet N11 and the fin-shaped active region FA. The lower gate portion 160 may surround the first lower nanosheet N11 and the second lower nanosheet N12 among the first lower nanosheet N11, the second lower nanosheet N12, and the third lower nanosheet N13 included in the lower nanosheet stack NSS1 in the vertical direction (e.g., Z direction).

In some embodiments, the plurality of upper gate portions 260 may each be disposed between each of the first upper nanosheet N21, the second upper nanosheet N22, and the third upper nanosheet N23 included in the upper nanosheet stack NSS2. The upper gate portion 260 may surround the second upper nanosheet N22 among the first upper nanosheet N21, the second upper nanosheet N22, and the third upper nanosheet N23 included in the upper nanosheet stack NSS2 in the vertical direction (e.g., Z direction).

As illustrated in FIG. 2, the plurality of gate lines 560 may each further include an intermediate gate portion 360 disposed between the plurality of lower gate portions 160 and the plurality of upper gate portions 260 and an uppermost gate portion 460. A thickness of each of the plurality of lower gate portions 160 and the plurality of upper gate portions 260 may be less than a thickness of each of the intermediate gate portion 360 and the uppermost gate portion 460 in the vertical direction (e.g., Z direction).

Each of the plurality of gate lines 560 may include metal, metal nitride, metal carbide, or a combination thereof. The metal may include Ti, W, Ru, Nb, Mo, Hf, Ni, Co, Pt, Yb, Tb, Dy, Er, and/or Pd. The metal nitride may include TiN and/or TaN. The metal carbide may be TiAlC. However, the material constituting the plurality of gate lines 560 is not necessarily limited to the above example.

As illustrated in FIGS. 2 and 4, a plurality of first recesses RI may be formed in the fin-shaped active region FA. A vertical level of the lowest surface of each of the plurality of first recesses R1 may be lower than a vertical level of the fin top surface FT of the fin-type active region FA.

As illustrated in FIGS. 2 and 4, a plurality of lower source/drain regions 130 may be disposed within the plurality of first recesses R1. The plurality of lower source/drain regions 130 may each be disposed adjacent to at least one of the plurality of lower gate portions 160. The plurality of lower source/drain regions 130 may each be disposed between a pair of adjacent lower gate portions 160. The plurality of lower source/drain regions 130 may each have surfaces facing the first lower nanosheet N11, the second lower nanosheet N12, and the third lower nanosheet N13 included in the adjacent lower nanosheet stack NSS1. The plurality of lower source/drain regions 130 may each contact the first lower nanosheet N11, the second lower nanosheet N12, and the third lower nanosheet N13 included in the adjacent lower nanosheet stack NSS1.

For example, the plurality of lower source/drain regions 130 may each include a first lower semiconductor pattern 131, a second lower semiconductor pattern 133, and a third lower semiconductor pattern 135, which are sequentially disposed inside each of the plurality of first recesses R1. The first lower semiconductor pattern 131 may contact the fin-type active region FA and the channel region on a bottom surface of the first recess R1. The third lower semiconductor pattern 135 may completely fill the first recess RI on the first lower semiconductor pattern 131 and the second lower semiconductor pattern 133.

For example, the first lower semiconductor pattern 131 and the second lower semiconductor pattern 133 may be disposed between the pair of adjacent lower gate portions 160 and may be U-shaped along a profile of the first recess R1.

For example, the plurality of lower source/drain regions 130 may each include the plurality of lower semiconductor patterns including a U-shaped outer layer on an inner wall of a first recess between the pair of lower gate portions and an inner layer completely filled in the first recess on the outer layer.

The first lower semiconductor pattern 131, the second lower semiconductor pattern 133, and the third lower semiconductor pattern 135 in the lower source/drain regions 130 may each include a Si₁₋ₓGeₓ layer (here, x≠0) doped with a p-type dopant.

In some embodiments, a concentration of the p-type dopant of the first lower semiconductor pattern 131 may be less than a concentration of the p-type dopant of the second lower semiconductor pattern 133. The concentration of the p-type dopant of the second lower semiconductor pattern 133 may be lower than a concentration of the p-type dopant of the third lower semiconductor pattern 135.

In some embodiments, the p-type dopant included in the lower source/drain region 130 may include boron (B), gallium (Ga), carbon (C), or a combination thereof, but is not necessarily limited to thereto.

As illustrated in FIGS. 2 and 3, a plurality of upper source/drain regions 210 may be disposed on the lower source/drain regions 130. The plurality of upper source/drain regions 210 may each be disposed adjacent to at least one of the plurality of upper gate portions 260. The plurality of upper source/drain regions 210 may be disposed between a pair of adjacent upper gate portions 260. The plurality of upper source/drain regions 210 may each have surfaces facing the first upper nanosheet N21, the second upper nanosheet N22, and the third upper nanosheet N23 included in the adjacent upper nanosheet stack NSS2. The plurality of upper source/drain regions 210 may each contact the first upper nanosheet N21, the second upper nanosheet N22, and the third upper nanosheet N23 included in the adjacent upper nanosheet stack NSS2. Hereinafter, the upper source/drain region 210 will be described in detail.

In some embodiments, the upper source/drain region 210 may include a first semiconductor pattern 211, a second semiconductor pattern 213, and a third semiconductor pattern 215.

For example, the first semiconductor pattern 211 may contact side surfaces of each of the first upper nanosheet N21, the second upper nanosheet N22, and the third upper nanosheet N23 included in the upper nanosheet stack NSS2. For example, a first surface 211_S1 of the first semiconductor pattern 211 may contact the side surfaces of each of the first upper nanosheet N21, the second upper nanosheet N22, and the third upper nanosheet N23.

The first semiconductor pattern 211 may be in the shape of protruding from the side surfaces of each of the first upper nanosheet N21, the second upper nanosheet N22, and the third upper nanosheet N23. For example, a second surface 211_S2 of the first semiconductor pattern 211 may have a round shape. The second surface 211_S2 of the first semiconductor pattern 211 may be opposite to the first surface 211_S1.

The first semiconductor pattern 211 may overlap each of the first upper nanosheet N21, the second upper nanosheet N22, and the third upper nanosheet N23 in the first horizontal direction (e.g., X direction). The first semiconductor pattern 211 might not overlap the plurality of upper gate portions 260 in the first horizontal direction (e.g., X direction).

For example, the second semiconductor pattern 213 may cover the first semiconductor pattern 211. For example, the second semiconductor pattern 213 may cover the second surface 211_S2 of the first semiconductor pattern 211. The second semiconductor pattern 213 may surround the second surface 211_S2 of the first semiconductor pattern 211. For example, the second semiconductor pattern 213 may completely cover the second surface 211_S2 of the first semiconductor pattern 211. The second semiconductor pattern 213 may completely surround the second surface 211_S2 of the first semiconductor pattern 211. For example, the second semiconductor pattern 213 may contact the second surface 211_S2 of the first semiconductor pattern 211.

The second semiconductor pattern 213 may include a part that does not overlap each of the first upper nanosheet N21, the second upper nanosheet N22, and the third upper nanosheet N23 in the first horizontal direction (e.g., X direction).

For example, the third semiconductor pattern 215 may cover the first semiconductor pattern 211 and the second semiconductor pattern 213. The third semiconductor pattern 215 may completely cover the first semiconductor pattern 211 and the second semiconductor pattern 213. For example, the third semiconductor pattern 215 may cover the first semiconductor pattern 211 and the second semiconductor pattern 213 between a pair of upper nanosheet stacks NSS2, and be filled between the pair of upper nanosheet stacks NSS2. For example, the third semiconductor pattern 215 may cover the first semiconductor pattern 211 and the second semiconductor pattern 213 between the pair of upper gate portions 260, and be filled between the pair of upper gate portions 260.

The third semiconductor pattern 215 may contact the second semiconductor pattern 213 and might not contact the first semiconductor pattern 211.

In some embodiments, the first semiconductor pattern 211, the second semiconductor pattern 213, and the third semiconductor pattern 215 may each include a silicon (Si) layer. For example, the first semiconductor pattern 211 may be a silicon (Si) layer including no dopant, and the second semiconductor pattern 213 and the third semiconductor pattern 215 may each a silicon (Si) layer including an n-type dopant. A concentration of the n-type dopant in the second semiconductor pattern 213 may be lower than a concentration of the n-type dopant in the third semiconductor pattern 215. For example, the n-type dopant may be arsenic (As), phosphorus (P), and/or carbon (C). In some embodiments, the n-type dopants of the second semiconductor pattern 213 and the third semiconductor pattern 215 may be selected as the same type. In some embodiments, the n-type dopant of the second semiconductor pattern 213 and the third semiconductor pattern 215 may be selected as different types.

In some embodiments, the first semiconductor pattern 211 may include a first island region 211_P1 protruding from the side surfaces of the first upper nanosheet N21, a second island region 211_P2 protruding from the side surfaces of the second upper nanosheet N22, and a third island region 211_P3 protruding from the side surfaces of the third upper nanosheet N23. The first island region 211_P1, the second island region 211_P2, and the third island region 211_P3 might not be connected to each other and may be separated from each other in the vertical direction (e.g., Z direction). For example, the first semiconductor pattern 211 may have an island shape protruding from the side surfaces of each of the first upper nanosheet N21, the second upper nanosheet N22, and the third upper nanosheet N23.

In some embodiments, the second semiconductor pattern 213 may include a first region 213_P1 surrounding the first island region 211_P1 of the first semiconductor pattern 211, a second region 213_P2 surrounding the second island region 211_P2, and a third region 213_P3 surrounding the third island region 211_P3. The first region 213_P1, the second region 213_P2, and the third region 213_P3 might not be connected to each other and may be separated from each other in the vertical direction (e.g., Z direction).

In some embodiments, the third semiconductor pattern 215 may be disposed between each of the first island region 211_P1, the second island region 211_P2, and the third island region 211_P3 of the first semiconductor pattern 211. For example, the third semiconductor pattern 215 may overlap the first island region 211_P1, the second island region 211_P2, and the third island region 211_P3 in the vertical direction (e.g., Z direction) between each of the first island region 211_P1, the second island region 211_P2, and the third island region 211_P3 of the first semiconductor pattern 211. Likewise, the third semiconductor pattern 215 may be disposed between each of the first region 213_P1, the second region 213_P2, and the third region 213_P3 of the second semiconductor pattern 213. For example, the third semiconductor pattern 215 may overlap the first region 213_P1, the second region 213_P2, and the third region 213_P3 of the second semiconductor pattern 213 in the vertical direction (e.g., Z direction) between each of the first region 213_P1, the second region 213_P2, and the third region 213_P3 of the second semiconductor pattern 213.

In some embodiments, the third semiconductor pattern 215 may include a part of the first semiconductor pattern 211 disposed on the third island region 211_P3. For example, the third semiconductor pattern 215 may be disposed between the third island region 211_P3 and an insulating liner 442. For example, the third semiconductor pattern 215 may overlap the third island region 211_P3 in the vertical direction (e.g., Z direction) on the third island region 211_P3. Likewise, the third semiconductor pattern 215 may include a part of the second semiconductor pattern 213 disposed on the third region 213_P3. For example, the third semiconductor pattern 215 may be disposed between the third region 213_P3 and the insulating liner 442. For example, the third semiconductor pattern 215 may overlap the third region 213_P3 in the vertical direction (e.g., Z direction) on the third region 213_P3.

In some embodiments, the third semiconductor pattern 215 may include a part of the first semiconductor pattern 211 disposed below the first island region 211_P1. For example, the third semiconductor pattern 215 may be disposed between the first island region 211_P1 and an isolation structure 330. For example, the third semiconductor pattern 215 may overlap the first island region 211_P1 in the vertical direction (e.g., Z direction) below the first island region 211_P1.

Likewise, the third semiconductor pattern 215 may include a part of the second semiconductor pattern 213 disposed below the first region 213_P1. For example, the third semiconductor pattern 215 may be disposed between the first region 213_P1 and the isolation structure 330. For example, the third semiconductor pattern 215 may overlap the first region 213_P1 in the vertical direction (e.g., Z direction) below the first region 213_P1.

In some embodiments, the third semiconductor pattern 215 may include a part that does not overlap the first semiconductor pattern 211 and the second semiconductor pattern 213 in the vertical direction (e.g., Z direction). For example, the third semiconductor pattern 215 may include a part that overlaps with the first semiconductor pattern 211 and the second semiconductor pattern 213 in the first horizontal direction (e.g., X direction), and does not overlap the first semiconductor pattern 211 and the second semiconductor pattern 213 in the vertical direction (e.g., Z direction).

In some embodiments, the third semiconductor pattern 215 may include a part that does not overlap the first semiconductor pattern 211 and the second semiconductor pattern 213 in the first horizontal direction (e.g., X direction). For example, the third semiconductor pattern 215 may include a part that overlaps with the first semiconductor pattern 211 and the second semiconductor pattern 213 in the vertical direction (e.g., Z direction), and does not overlap the first semiconductor pattern 211 and the second semiconductor pattern 213 in the first horizontal direction (e.g., X direction).

In some embodiments, a lower surface and a top surface of the upper source/drain region 210 may each include the uppermost portion and the lowermost portion. Herein, the uppermost portion of the lower surface or the top surface may refer to a portion of the lower surface or the top surface having the highest vertical level. The lowermost portion of the lower surface or the top surface may refer to a portion of the lower surface or the top surface having the lowest vertical level.

In some embodiments, at least a part of the lower surface of the upper source/drain region 210 may be the lower surface of the third semiconductor pattern 215. For example, the lowermost portion of the lower surface of the upper source/drain region 210 may be a part of the lower surface of the third semiconductor pattern 215. For example, the uppermost portion of the lower surface of the upper source/drain region 210 may be a part of the lower surface of the third semiconductor pattern 215. For example, the lower surface of the upper source/drain region 210 may be the lower surface of the third semiconductor pattern 215.

In some embodiments, at least a part of the top surface of the upper source/drain region 210 may be the top surface of the third semiconductor pattern 215. For example, the lowermost portion of the top surface of the upper source/drain region 210 may be a part of the top surface of the third semiconductor pattern 215. For example, the uppermost portion of the top surface of the upper source/drain region 210 may be a part of the top surface of the third semiconductor pattern 215. For example, the top surface of the upper source/drain region 210 may be the top surface of the third semiconductor pattern 215.

For example, in the upper source/drain region 210, the third semiconductor pattern 215 may include at least a part having a vertical level lower than the vertical level of each of the first semiconductor pattern 211 and the second semiconductor pattern 213. Likewise, the third semiconductor pattern 215 may include at least a part having a vertical level higher than the vertical level of each of the first semiconductor pattern 211 and the second semiconductor pattern 213.

In some embodiments, the uppermost portion of the lower surface and the lowermost portion of the top surface of the upper source/drain region 210 might not overlap the first semiconductor pattern 211 and the second semiconductor pattern 213 in the vertical direction (e.g., Z direction).

In some embodiments, the lowermost portion of the lower surface and the uppermost portion of the top surface of the upper source/drain region 210 may overlap the first semiconductor pattern 211 and the second semiconductor pattern 213 in the vertical direction (e.g., Z direction).

As illustrated in FIG. 2, the isolation structure 330 may be disposed between the lower source/drain region 130 and the upper source/drain region 210. The isolation structure 330 may overlap the lower source/drain region 130 and the upper source/drain region 210 in the vertical direction (e.g., Z direction). The isolation structure 330 may contact each of the lower source/drain region 130 and the upper source/drain region 210. For example, the isolation structure 330 may contact the top surface of the lower source/drain region 130 and the lower surface of the upper source/drain region 210. For example, the isolation structure 330 may contact the third semiconductor pattern 215 of the upper source/drain region 210.

In embodiments, the isolation structure 330 may include an insulating spacer 310, an isolation insulating layer 311, and an air gap 320. The insulating spacer 310 and the isolation insulating layer 311 may each include nitride. The air gap 320 may be surrounded by the insulating spacer 310 and the isolation insulating layer 311. The isolation insulating layer 311 may cover the lower surface of the upper source/drain region 210. The isolation insulating layer 311 may contact the third semiconductor pattern 215.

As illustrated in FIG. 2, gate dielectric layers may be disposed between the lower and upper nanosheet stacks NSS1 and NSS2 and the gate lines 560. For example, a lower gate dielectric layer 151 may be disposed between the lower nanosheet stack NSS1 and the lower gate portion 160. For example, an upper gate dielectric layer 251 may be disposed between the upper nanosheet stack NSS2 and the upper gate portion 260. For example, an intermediate gate dielectric layer 351 may be disposed between the intermediate gate portion 360 and each of the lower nanosheet stack NSS1 and the upper nanosheet stack NSS2. For example, an uppermost gate dielectric layer 451 may be disposed between the uppermost gate portion 460 and the upper nanosheet stack NSS2.

In some embodiments, a gate dielectric layer may have a stacked structure of an interface dielectric layer and a high dielectric layer. The interface dielectric layer may include a low dielectric material layer (e.g., a material with a dielectric constant than is lower than or equal to that of silicon oxide) with a dielectric constant of about 9 or less, for example, a silicon oxide layer, a silicon oxynitride layer, or a combination thereof. In some embodiments, the interface dielectric layer may be omitted. The high-k dielectric layer may include a material with a higher dielectric constant than the silicon oxide layer. For example, the high dielectric layer may have a dielectric constant of about 10 to about 25. The high-k dielectric layer may include hafnium oxide, but is not necessarily limited thereto.

As illustrated in FIG. 2, a top surface of each of the uppermost gate portion 460 and the uppermost gate dielectric layer 451 may be covered with a capping insulating pattern 468. The capping insulating pattern 468 may include a silicon nitride layer.

Both sidewalls of the uppermost gate portion 460 and the capping insulating pattern 468 may be covered with outer insulating spacers 418. The outer insulating spacers 418 may cover both sidewalls of the uppermost gate portion 460 on the top surfaces of the plurality of upper nanosheet stacks NSS2. The outer insulating spacers 418 may be spaced apart from the uppermost gate portion 460 with the uppermost gate dielectric layer 451 therebetween.

The plurality of outer insulating spacers 418 may each include silicon nitride, silicon oxide, SiCN, SiBN, SiON, SiOCN, SiBCN, SiOC, or a combination thereof. As used herein, the terms “SiCN”, “SiBN”, “SiON”, “SiOCN”, “SiBCN”, and “SiOC” mean materials including elements included in the terms, and are not necessarily chemical equations exhibiting a stoichiometric relationship.

On the substrate 102, the plurality of upper source/drain regions 210 and the plurality of outer insulating spacers 418 may be covered with the insulating liner 442. In some embodiments, the insulating liner 442 may be omitted. An inter-gate insulating layer 444 may be disposed on the insulating liner 442. When the insulating liner 442 is omitted, the inter-gate insulating layer 444 may contact the plurality of upper source/drain regions 210.

The insulating liner 442 and the inter-gate insulating layer 444 may be sequentially disposed on the plurality of upper source/drain regions 210. The insulating liner 442 and the inter-gate insulating layer 444 may form an insulating structure. In some embodiments, the insulating liner 442 may include silicon nitride, SiCN, SiBN, SiON, SiOCN, SiBCN, or a combination thereof, but is not necessarily limited thereto. The inter-gate insulating layer 444 may include a silicon oxide layer, but is not necessarily limited thereto.

As illustrated in FIGS. 2 and 4, both sidewalls of each of the plurality of lower gate portions 160 may be spaced apart from the lower source/drain region 130 with the lower gate dielectric layer 151 disposed therebetween. The lower gate dielectric layer 151 may be disposed between the lower gate portion 160 and each of the first lower nanosheet N11, the second lower nanosheet N12, and the third lower nanosheet N13, and between the lower gate portion 160 and the lower source/drain region 130.

As illustrated in FIGS. 2 and 3, both sidewalls of each of the plurality of upper gate portions 260 may be spaced apart from the upper source/drain region 210 with the upper gate dielectric layer 251 disposed therebetween. The upper gate dielectric layer 251 may be disposed between the upper gate portion 260 and each of the first upper nanosheet N21, the second upper nanosheet N22, and the third upper nanosheet N23, between the first upper nanosheet N21 and the fin top surface FT of the fin-type active region FA, and between the upper gate portion 260 and the upper source/drain region 210.

As illustrated in FIG. 2, both sidewalls of each of the plurality of intermediate gate portions 360 may be spaced apart from the isolation structure 330 with the intermediate gate dielectric layer 351 disposed therebetween. The intermediate gate dielectric layer 351 may be disposed between the intermediate gate portion 360 and each of the first upper nanosheet N21 and the third lower nanosheet N13, and between the intermediate gate portion 360 and the isolation structure 330.

In some embodiments, the lower stack 100 may include a lower nanosheet transistor including a plurality of lower channel regions, the plurality of lower gate portions 160, and the plurality of lower source/drain regions 130. For example, the lower stack 100 may include a p-channel metal-oxide-semiconductor (PMOS) device.

For example, the plurality of lower nanosheet stacks NSS1 may be respectively disposed on the fin top surfaces FT of the plurality of fin-type active regions FA in regions where the plurality of fin-type active regions FA and the plurality of lower gate portions 160 intersect and face the fin top surfaces FT of the fin-type active regions FA at positions spaced apart from the fin-type active regions FA. A plurality of lower nanosheet transistors may be formed on parts of the substrate 102 where the plurality of fin-type active regions FA and the plurality of lower gate portions 160 intersect.

In embodiments, the upper stack 200 may include an upper nanosheet transistor including a plurality of upper channel regions, the plurality of upper gate portions 260, and the plurality of upper source/drain regions 210. For example, the upper stack 200 may include an n-channel metal-oxide-semiconductor (NMOS) device.

For example, the plurality of upper nanosheet stacks NSS2 may be respective disposed on the fin top surfaces FT of the plurality of fin-type active regions FA in regions where the plurality of fin-type active regions FA and the plurality of upper gate portions 260 intersect and face the fin top surfaces FT of the fin-type active regions FA at positions spaced apart from the fin-type active regions FA. A plurality of upper nanosheet transistors may be formed on parts of the substrate 102 where the plurality of fin-type active regions FA and the plurality of upper gate portions 260 intersect.

The integrated circuit device 10 described with reference to FIGS. 1 to 4 may have enhanced performance and reliability. For example, transistors each in which the upper source/drain regions 210 are stacked are may be vertically stacked on the lower source/drain region 130, and thus, cell interference may be minimized, and many transistors may be integrated into a narrower space.

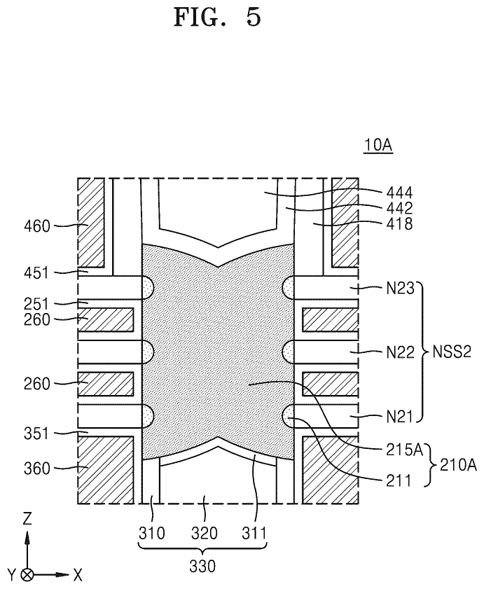

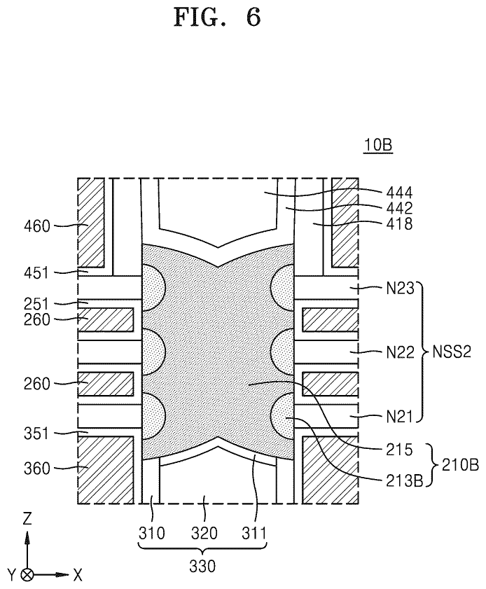

FIGS. 5 and 6 are enlarged cross-sectional views illustrating integrated circuit devices 10A and 10B according to some embodiments. For example, FIGS. 5 and 6 are enlarged cross-sectional views of a region corresponding to the region EX1 of FIG. 2. Hereinafter, to the extent that an element is not described in detail with respect to this figure, it may be understood that the element is at least similar to a corresponding element that has been described elsewhere within the present disclosure, for example, with respect to FIGS. 1 to 4.

Referring to FIG. 5, the integrated circuit device 10A may include an upper source/drain region 210A adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 210A may include the first semiconductor pattern 211 and a third semiconductor pattern 215A covering the first semiconductor pattern 211.

For example, the first semiconductor pattern 211 may contact side surfaces of each of the first upper nanosheet N21, the second upper nanosheet N22, and the third upper nanosheet N23.

For example, the third semiconductor pattern 215A may cover the first semiconductor pattern 211. The third semiconductor pattern 215A may contact the first semiconductor pattern 211 and completely cover the first semiconductor pattern 211.

Referring to FIG. 6, the integrated circuit device 10B may include an upper source/drain region 210B adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 210B may include a second semiconductor pattern 213B and the third semiconductor pattern 215 covering the second semiconductor pattern 213B.

For example, the second semiconductor pattern 213B may contact side surfaces of each of the first upper nanosheet N21, the second upper nanosheet N22, and the third upper nanosheet N23. The second semiconductor pattern 213B may include a part that does not overlap each of the first upper nanosheet N21, the second upper nanosheet N22, and the third upper nanosheet N23 in the first horizontal direction (e.g., X direction).

For example, the third semiconductor pattern 215 may cover the second semiconductor pattern 213B. The third semiconductor pattern 215 may contact the second semiconductor pattern 213B and completely cover the second semiconductor pattern 213B.

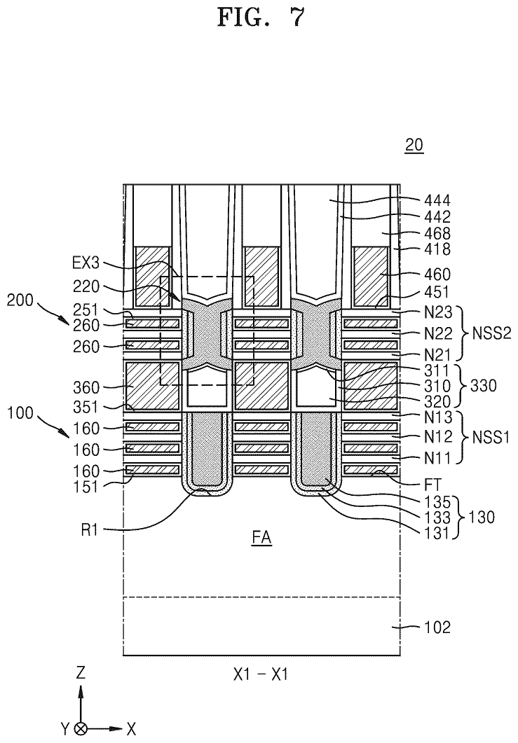

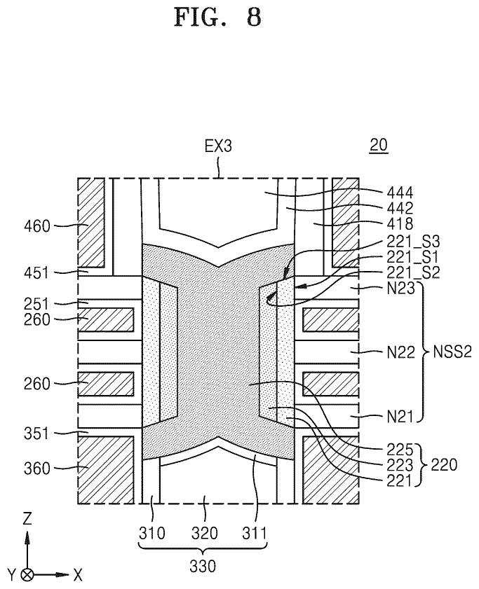

FIG. 7 is a cross-sectional view illustrating an integrated circuit device 20 according to some embodiments. FIG. 8 is an enlarged cross-sectional view of a region EX3 of FIG. 7. Hereinafter, to the extent that an element is not described in detail with respect to this figure, it may be understood that the element is at least similar to a corresponding element that has been described elsewhere within the present disclosure, for example, with respect to FIGS. 1 to 4.

Referring to FIGS. 7 and 8, the integrated circuit device 20 may include the lower stack 100 and the upper stack 200. The lower stack 100 may include the plurality of lower gate portions 160, the plurality of lower nanosheet stacks NSS1, and the lower source/drain region 130. The upper stack 200 may include the plurality of upper gate portions 260, the plurality of upper nanosheet stacks NSS2, and the upper source/drain region 220.

In some embodiments, the upper source/drain region 220 may include a first semiconductor pattern 221, a second semiconductor pattern 223, and a third semiconductor pattern 225.

For example, the first semiconductor pattern 221 may contact side surfaces of each of the first upper nanosheet N21, the second upper nanosheet N22, and the third upper nanosheet N23 included in the upper nanosheet stack NSS2. For example, a first surface 221_S1 of the first semiconductor pattern 211 may contact the side surfaces of each of the first upper nanosheet N21, the second upper nanosheet N22, and the third upper nanosheet N23. The first semiconductor pattern 221 may overlap each of the first upper nanosheet N21, the second upper nanosheet N22, and the third upper nanosheet N23 in the first horizontal direction (e.g., X direction).

For example, the second semiconductor pattern 223 may cover the first semiconductor pattern 221. For example, the second semiconductor pattern 223 may cover a second surface 221_S2 of the first semiconductor pattern 221. For example, the second semiconductor pattern 223 may contact the second surface 221_S2 of the first semiconductor pattern 221. The second surface 221_S2 of the first semiconductor pattern 221 may be opposite to the first surface 221_S1.

The second semiconductor pattern 223 might not be disposed on a third surface 221_S3 of the first semiconductor pattern 221. The third surface 221_S3 of the first semiconductor pattern 221 may be a surface connecting the first surface 221_S1 to the second surface 221_S2. The second semiconductor pattern 223 might not contact the third surface 221_S3 of the first semiconductor pattern 221.

In some embodiments, the first semiconductor pattern 221 may integrally extend on side surfaces of each of the first upper nanosheet N21, the second upper nanosheet N22, and the third upper nanosheet N23 of the upper nanosheet stack NSS2 and side surfaces of the upper gate portion 260. For example, the first semiconductor pattern 221 may extend in the vertical direction (e.g., Z direction) on the side surfaces of each of the first upper nanosheet N21, the second upper nanosheet N22, and the third upper nanosheet N23 and the side surfaces of the upper gate portion 260. For example, the first surface 221_S1 and the second surface 221_S2 of the first semiconductor pattern 221 may each extend parallel to the side surfaces of each of the first upper nanosheet N21, the second upper nanosheet N22, and the third upper nanosheet N23. For example, a thickness of the first semiconductor pattern 221 in the first horizontal direction (e.g., X direction) may be constant in the vertical direction (e.g., Z direction).

The first semiconductor pattern 221 may include a part that does not overlap each of the first upper nanosheet N21, the second upper nanosheet N22, and the third upper nanosheet N23 in the first horizontal direction (e.g., X direction). The first semiconductor pattern 221 may include a part that overlaps each of the plurality of upper gate portions 260 in the first horizontal direction (e.g., X direction).

In some embodiments, the second semiconductor pattern 223 may integrally extend on the side surfaces of each of the first upper nanosheet N21, the second upper nanosheet N22, and the third upper nanosheet N23 of the upper nanosheet stack NSS2 and the side surfaces of the upper gate portion 260. For example, the second semiconductor pattern 223 may extend in the vertical direction (e.g., Z direction) on the side surfaces of each of the first upper nanosheet N21, the second upper nanosheet N22, and the third upper nanosheet N23 and the side surfaces of the upper gate portion 260. The second semiconductor pattern 223 may extend on the second surface 221_S2 of the first semiconductor pattern 221 in parallel with the second surface 221_S2 of the first semiconductor pattern 221. For example, a thickness of the second semiconductor pattern 223 in the first horizontal direction (e.g., X direction) may be constant in the vertical direction (e.g., Z direction).

The second semiconductor pattern 223 may include a part that does not overlap each of the first upper nanosheet N21, the second upper nanosheet N22, and the third upper nanosheet N23 in the first horizontal direction (e.g., X direction). The second semiconductor pattern 223 may include a part that overlaps each of the plurality of upper gate portions 260 in the first horizontal direction (e.g., X direction).

For example, the third semiconductor pattern 225 may cover the first semiconductor pattern 221 and the second semiconductor pattern 223. The third semiconductor pattern 225 may completely cover the first semiconductor pattern 221 and the second semiconductor pattern 223. For example, the third semiconductor pattern 225 may cover the first semiconductor pattern 221 and the second semiconductor pattern 223 between a pair of upper nanosheet stacks NSS2, and be filled between the pair of upper nanosheet stacks NSS2. For example, the third semiconductor pattern 225 may cover the first semiconductor pattern 221 and the second semiconductor pattern 223 between a pair of upper gate portions 260, and be filled between the pair of upper gate portions 260.

The third semiconductor pattern 225 may contact both the first semiconductor pattern 221 and the second semiconductor pattern 223. For example, the third semiconductor pattern 225 may contact the third surface 221_S3 of the first semiconductor pattern 221.

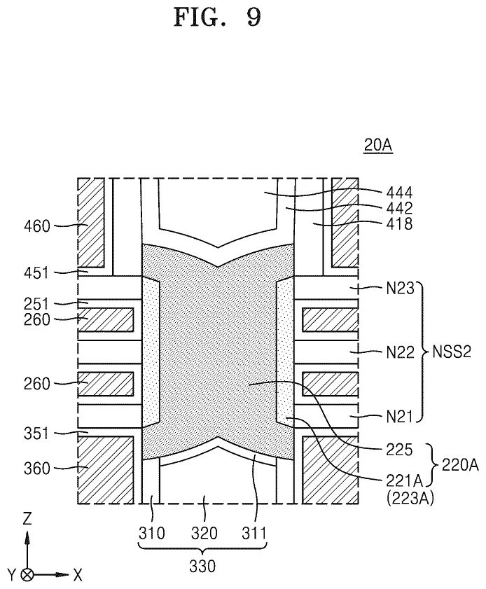

FIG. 9 is an enlarged cross-sectional view illustrating an integrated circuit device 20A according to some embodiments. For example, FIG. 9 is an enlarged cross-sectional view of a region corresponding to the region EX3 of FIG. 7. Hereinafter, to the extent that an element is not described in detail with respect to this figure, it may be understood that the element is at least similar to a corresponding element that has been described elsewhere within the present disclosure, for example, with respect to FIGS. 7 and 8.

Referring to FIG. 9, the integrated circuit device 20A may include an upper source/drain region 220A adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 220A may include a first semiconductor pattern 221A and the third semiconductor pattern 225 covering the first semiconductor pattern 221A.

For example, the first semiconductor pattern 221A may contact side surfaces of each of the first upper nanosheet N21, the second upper nanosheet N22, and the third upper nanosheet N23, and extend in the vertical direction (e.g., Z direction). The third semiconductor pattern 225 may cover the first semiconductor pattern 221A and contact the first semiconductor pattern 221A.

In some embodiments, the upper source/drain region 220A may include a second semiconductor pattern 223A and the third semiconductor pattern 225 covering the second semiconductor pattern 223A.

For example, the second semiconductor pattern 223A may contact the side surfaces of each of the first upper nanosheet N21, the second upper nanosheet N22, and the third upper nanosheet N23, and extend in the vertical direction (e.g., Z direction). The third semiconductor pattern 225 may cover the second semiconductor pattern 223A and contact the second semiconductor pattern 223A.

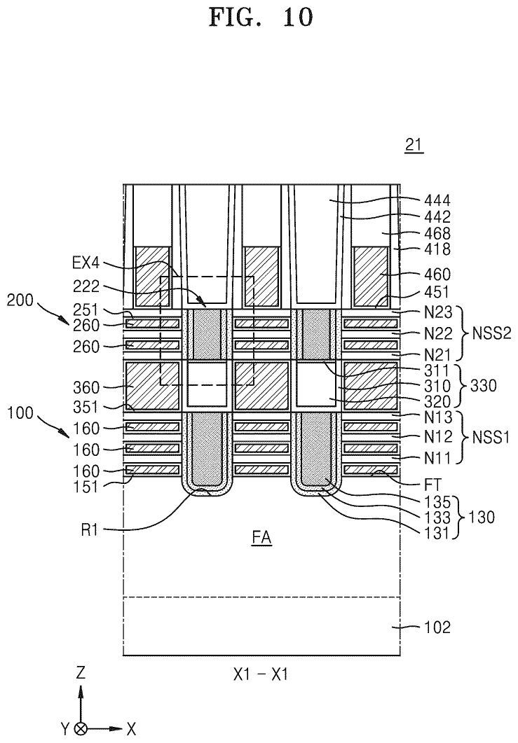

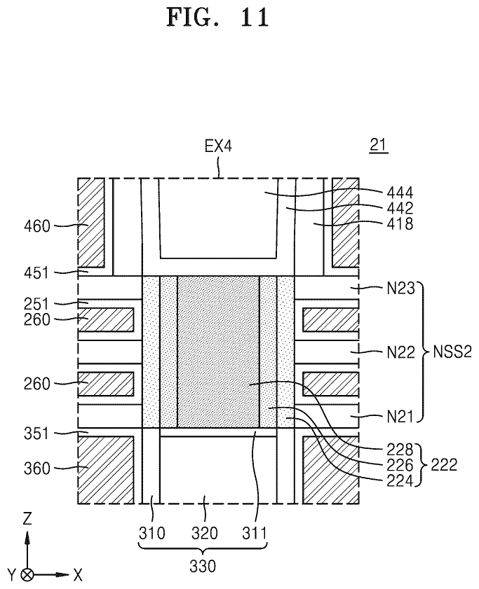

FIG. 10 is a cross-sectional view illustrating an integrated circuit device 21 according to some embodiments. FIG. 11 is an enlarged cross-sectional view of a region EX4 of FIG. 10. Hereinafter, to the extent that an element is not described in detail with respect to this figure, it may be understood that the element is at least similar to a corresponding element that has been described elsewhere within the present disclosure, for example, with respect to FIGS. 7 and 8.

Referring to FIGS. 10 and 11, the integrated circuit device 21 may include the lower stack 100 and the upper stack 200. The lower stack 100 may include the plurality of lower gate portions 160, the plurality of lower nanosheet stacks NSS1, and the lower source/drain region 130. The upper stack 200 may include the plurality of upper gate portions 260, the plurality of upper nanosheet stacks NSS2, and an upper source/drain region 222.

In some embodiments, the upper source/drain region 222 may include a first semiconductor pattern 224, a second semiconductor pattern 226, and a third semiconductor pattern 228.

For example, the first semiconductor pattern 224 may contact side surfaces of each of the first upper nanosheet N21, the second upper nanosheet N22, and the third upper nanosheet N23 included in the upper nanosheet stack NSS2. The first semiconductor pattern 224 may integrally extend on the side surfaces of each of the first upper nanosheet N21, the second upper nanosheet N22, and the third upper nanosheet N23 and the side surfaces of the upper gate portion 260.

For example, the second semiconductor pattern 226 may cover the first semiconductor pattern 224. The second semiconductor pattern 226 may integrally extend on the side surfaces of each of the first upper nanosheet N21, the second upper nanosheet N22, and the third upper nanosheet N23 and the side surfaces of the upper gate portion 260.

For example, the third semiconductor pattern 228 may cover the first semiconductor pattern 224 and the second semiconductor pattern 226. The third semiconductor pattern 228 may contact the second semiconductor pattern 226 and not contact the first semiconductor pattern 224.

In some embodiments, the third semiconductor pattern 228 might not include a part that does not overlap the first semiconductor pattern 224 and the second semiconductor pattern 226 in the first horizontal direction (e.g., X direction). The third semiconductor pattern 228 might not include a part that overlaps the first semiconductor pattern 224 and the second semiconductor pattern 226 in the vertical direction (e.g., Z direction).

In some embodiments, the third semiconductor pattern 228 might not include a part located above and a part located below the first semiconductor pattern 224 and the second semiconductor pattern 226.

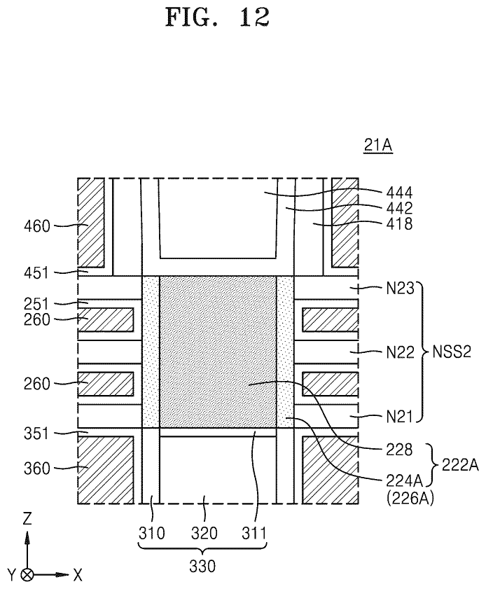

FIG. 12 is an enlarged cross-sectional view illustrating an integrated circuit device 21A according to some embodiments. For example, FIG. 12 is an enlarged cross-sectional view of a region corresponding to the region EX4 of FIG. 10. Hereinafter, to the extent that an element is not described in detail with respect to this figure, it may be understood that the element is at least similar to a corresponding element that has been described elsewhere within the present disclosure, for example, with respect to FIGS. 10 and 11.

Referring to FIG. 12, the integrated circuit device 21A may include an upper source/drain region 222A adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 222A may include a first semiconductor pattern 224A and a third semiconductor pattern 228 covering the first semiconductor pattern 224A.

For example, the first semiconductor pattern 224A may contact side surfaces of each of the first upper nanosheet N21, the second upper nanosheet N22, and the third upper nanosheet N23, and extend in the vertical direction (e.g., Z direction). The third semiconductor pattern 228 may cover the first semiconductor pattern 224A and contact the first semiconductor pattern 224A.

In some embodiments, the upper source/drain region 222A may include a second semiconductor pattern 226A and the third semiconductor pattern 228 covering the second semiconductor pattern 226A.

For example, the second semiconductor pattern 226A may contact the side surfaces of each of the first upper nanosheet N21, the second upper nanosheet N22, and the third upper nanosheet N23, and extend in the vertical direction (e.g., Z direction). The third semiconductor pattern 228 may cover the second semiconductor pattern 226A and contact the second semiconductor pattern 226A.

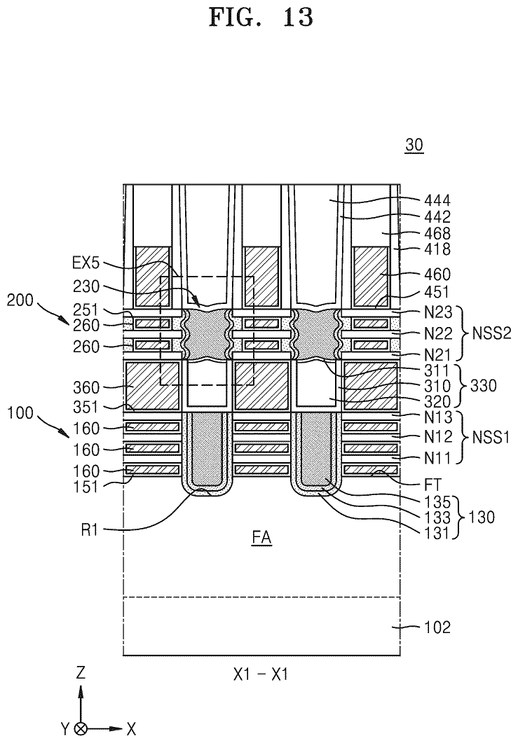

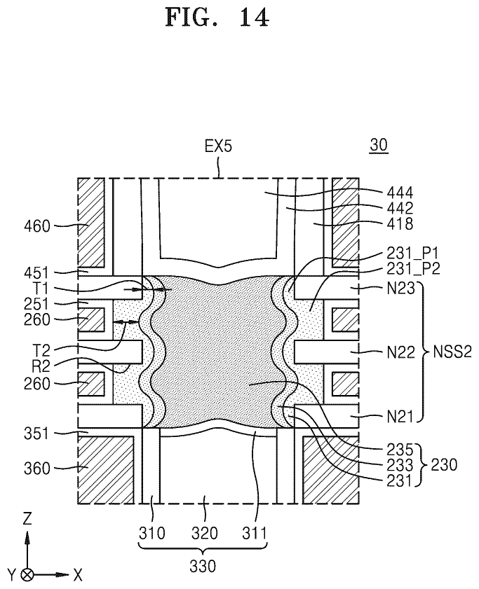

FIG. 13 is a cross-sectional view illustrating an integrated circuit device 30 according to some embodiments. FIG. 14 is an enlarged cross-sectional view of a region EX5 of FIG. 13. Hereinafter, to the extent that an element is not described in detail with respect to this figure, it may be understood that the element is at least similar to a corresponding element that has been described elsewhere within the present disclosure, for example, with respect to FIGS. 1 to 4.

Referring to FIGS. 13 and 14, the integrated circuit device 30 may include the lower stack 100 and the upper stack 200. The lower stack 100 may include the plurality of lower gate portions 160, the plurality of lower nanosheet stacks NSS1, and the lower source/drain region 130. The upper stack 200 may include the plurality of upper gate portions 260, the plurality of upper nanosheet stacks NSS2, and an upper source/drain region 230.

In some embodiments, the upper source/drain region 230 may include a first semiconductor pattern 231, a second semiconductor pattern 233, and a third semiconductor pattern 235.

For example, the first semiconductor pattern 231 may contact side surfaces of each of the first upper nanosheet N21, the second upper nanosheet N22, and the third upper nanosheet N23 included in the upper nanosheet stack NSS2.

The first semiconductor pattern 231 may include a part disposed between each of the first upper nanosheet N21, the second upper nanosheet N22, and the third upper nanosheet N23. For example, the first semiconductor pattern 231 may include a part disposed inside a second recess R2 between the first upper nanosheet N21 and the second upper nanosheet N22, and between the second upper nanosheet N22 and the third upper nanosheet N23.

The first semiconductor pattern 231 may include a part that overlaps each of the first upper nanosheet N21, the second upper nanosheet N22, and the third upper nanosheet N23 in the vertical direction (e.g., Z direction). For example, the part of the first semiconductor pattern 231 disposed inside the second recess R2 may overlap each of the first upper nanosheet N21, the second upper nanosheet N22, and the third upper nanosheet N23 in the vertical direction (e.g., Z direction).

The first semiconductor pattern 231 may integrally extend on side surfaces of each of the first upper nanosheet N21, the second upper nanosheet N22, and the third upper nanosheet N23 of the upper nanosheet stack NSS2 and side surfaces of the upper gate portion 260.

In some embodiments, the first semiconductor pattern 231 may include a first portion 231_P1 that overlaps each of the first upper nanosheet N21, the second upper nanosheet N22, and the third upper nanosheet N23 in the first horizontal direction (e.g., X direction), and a second portion 231_P2 that does not overlap each of the first upper nanosheet N21, the second upper nanosheet N22, and the third upper nanosheet N23 in the first horizontal direction (e.g., X direction). The second portion 231_P2 of the first semiconductor pattern 231 may include a part disposed inside the second recess R2. The second portion 231_P2 of the first semiconductor pattern 231 may overlap the plurality of upper gate portions 260 in the first horizontal direction (e.g., X direction).

A thickness T1 of the first portion 231_P1 of the first semiconductor pattern 231 in the first horizontal direction (e.g., X direction) may be less than a thickness T2 of the second portion 231_P2 in the first horizontal direction (e.g., X direction). For example, a thickness of the first semiconductor pattern 231 in the first horizontal direction (e.g., X direction) on side surfaces of the first upper nanosheet N21, the second upper nanosheet N22, and the third upper nanosheet N23 may be less than that on side surfaces of the plurality of upper gate portions 260.

For example, the second semiconductor pattern 233 may cover the first semiconductor pattern 231. For example, the second semiconductor pattern 233 may contact the first semiconductor pattern 231. The second semiconductor pattern 233 may be conformally disposed on the first semiconductor pattern 231.

In some embodiments, the second semiconductor pattern 233 may integrally extend on the side surfaces of each of the first upper nanosheet N21, the second upper nanosheet N22, and the third upper nanosheet N23 of the upper nanosheet stack NSS2 and the side surfaces of the upper gate portion 260. For example, the second semiconductor pattern 233 may extend integrally on the first semiconductor pattern 231.

The second semiconductor pattern 233 may include a part that does not overlap each of the first upper nanosheet N21, the second upper nanosheet N22, and the third upper nanosheet N23 in the first horizontal direction (e.g., X direction). The second semiconductor pattern 233 may include a part that overlaps each of the plurality of upper gate portions 260 in the first horizontal direction (e.g., X direction).

For example, the third semiconductor pattern 235 may cover the first semiconductor pattern 231 and the second semiconductor pattern 233. The third semiconductor pattern 235 may completely cover the first semiconductor pattern 231 and the second semiconductor pattern 233. For example, the third semiconductor pattern 235 may cover the first semiconductor pattern 231 and the second semiconductor pattern 233, between a pair of upper nanosheet stacks NSS2, and be filled between the pair of upper nanosheet stacks NSS2. For example, the third semiconductor pattern 235 may cover the first semiconductor pattern 231 and the second semiconductor pattern 233, between a pair of upper gate portions 260, and be filled between the pair of upper gate portions 260.

The third semiconductor pattern 235 may contact the second semiconductor pattern 233. The third semiconductor pattern 235 might not contact the first semiconductor pattern 231.

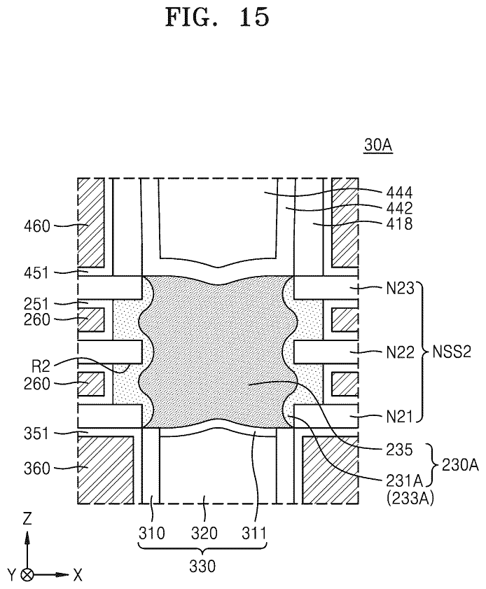

FIG. 15 is an enlarged cross-sectional view illustrating an integrated circuit device 30A according to some embodiments. For example, FIG. 15 is an enlarged cross-sectional view of a region corresponding to the region EX5 of FIG. 13. Hereinafter, to the extent that an element is not described in detail with respect to this figure, it may be understood that the element is at least similar to a corresponding element that has been described elsewhere within the present disclosure, for example, with respect to FIGS. 13 and 14.

Referring to FIG. 15, the integrated circuit device 30 may include an upper source/drain region 230A adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 230A may include a first semiconductor pattern 231A and the third semiconductor pattern 235 covering the first semiconductor pattern 231A.

For example, the first semiconductor pattern 231A may contact side surfaces of each of the first upper nanosheet N21, the second upper nanosheet N22, and the third upper nanosheet N23, and integrally extend on side surfaces of each of the first upper nanosheet N21, the second upper nanosheet N22, and the third upper nanosheet N23 and side surfaces of the upper gate portion 260. The first semiconductor pattern 231A may include a part disposed between each of the first upper nanosheet N21, the second upper nanosheet N22, and the third upper nanosheet N23. For example, the first semiconductor pattern 231A may include a part disposed inside the second recess R2 between the first upper nanosheet N21 and the second upper nanosheet N22, and between the second upper nanosheet N22 and the third upper nanosheet N23. The third semiconductor pattern 235 may cover the first semiconductor pattern 231A and contact the first semiconductor pattern 231A.

In some embodiments, the upper source/drain region 230A may include a second semiconductor pattern 233A and the third semiconductor pattern 235 covering the second semiconductor pattern 233A.

For example, the second semiconductor pattern 233A may contact the side surfaces of each of the first upper nanosheet N21, the second upper nanosheet N22, and the third upper nanosheet N23, and integrally extend on the side surfaces of each of the first upper nanosheet N21, the second upper nanosheet N22, and the third upper nanosheet N23 and the side surfaces of the upper gate portion 260. The second semiconductor pattern 233A may include a part disposed between each of the first upper nanosheet N21, the second upper nanosheet N22, and the third upper nanosheet N23. For example, the second semiconductor pattern 233A may include a part disposed inside the second recess R2 between the first upper nanosheet N21 and the second upper nanosheet N22, and between the second upper nanosheet N22 and the third upper nanosheet N23. The third semiconductor pattern 235 may cover the second semiconductor pattern 233A and contact the second semiconductor pattern 233A.

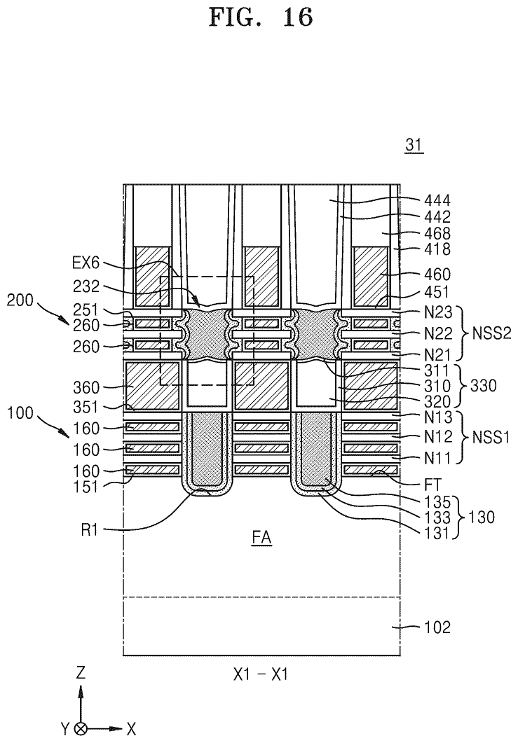

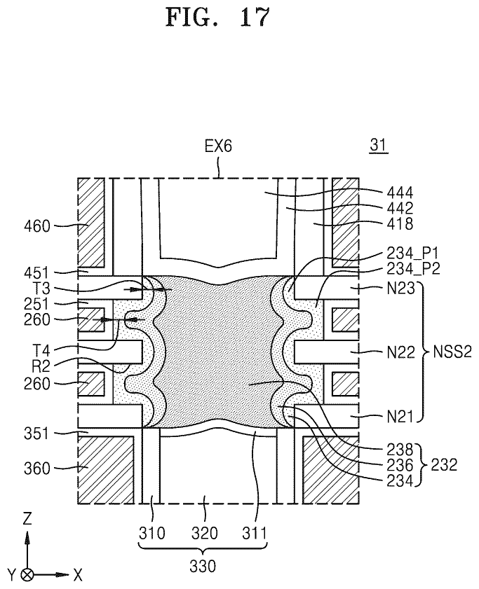

FIG. 16 is a cross-sectional view illustrating an integrated circuit device 31 according to some embodiments. FIG. 17 is an enlarged cross-sectional view of a region EX6 of FIG. 16. Hereinafter, to the extent that an element is not described in detail with respect to this figure, it may be understood that the element is at least similar to a corresponding element that has been described elsewhere within the present disclosure, for example, with respect to FIGS. 13 and 14.

Referring to FIGS. 16 and 17, the integrated circuit device 31 may include the lower stack 100 and the upper stack 200. The lower stack 100 may include the plurality of lower gate portions 160, the plurality of lower nanosheet stacks NSS1, and the lower source/drain region 130. The upper stack 200 may include the plurality of upper gate portions 260, the plurality of upper nanosheet stacks NSS2, and the upper source/drain region 232.

In some embodiments, the upper source/drain region 232 may include a first semiconductor pattern 234, a second semiconductor pattern 236, and a third semiconductor pattern 238.

For example, the first semiconductor pattern 234 may contact side surfaces of each of the first upper nanosheet N21, the second upper nanosheet N22, and the third upper nanosheet N23 included in the upper nanosheet stack NSS2. The first semiconductor pattern 234 may integrally extend on side surfaces of each of the first upper nanosheet N21, the second upper nanosheet N22, and the third upper nanosheet N23 and side surfaces of the upper gate portion 260.

The first semiconductor pattern 234 may include a first portion 234_P1 that overlaps the first upper nanosheet N21, the second upper nanosheet N22, and the third upper nanosheet N23 in the first horizontal direction (e.g., X direction) and a second portion 234_P2 that does not overlap the first upper nanosheet N21, the second upper nanosheet N22, and the third upper nanosheet N23 in the first horizontal direction (e.g., X direction). The second portion 234_P2 of the first semiconductor pattern 234 may include a part disposed inside the second recess R2.

A thickness T3 of the first portion 234_P1 of the first semiconductor pattern 234 in the first horizontal direction (e.g., X direction) may be the same as a thickness T4 of the second portion 234_P2 in the first horizontal direction (e.g., X direction). For example, a thickness of the first semiconductor pattern 234 in the first horizontal direction (e.g., X direction) on side surfaces of the first upper nanosheet N21, the second upper nanosheet N22, and the third upper nanosheet N23 may be the same as that on side surfaces of the plurality of upper gate portions 260. The first semiconductor pattern 234 may be conformally formed on the side surfaces of each of the first upper nanosheet N21, the second upper nanosheet N22, and the third upper nanosheet N23 and the side surfaces of the upper gate portion 260.

For example, the second semiconductor pattern 236 may cover the first semiconductor pattern 234. The second semiconductor pattern 236 may integrally extend on the side surfaces of each of the first upper nanosheet N21, the second upper nanosheet N22, and the third upper nanosheet N23 and the side surfaces of the upper gate portion 260. The second semiconductor pattern 236 may be conformally disposed on the first semiconductor pattern 234.

For example, the third semiconductor pattern 238 may cover the first semiconductor pattern 234 and the second semiconductor pattern 236. The third semiconductor pattern 238 may contact the second semiconductor pattern 236 and might not contact the first semiconductor pattern 234.

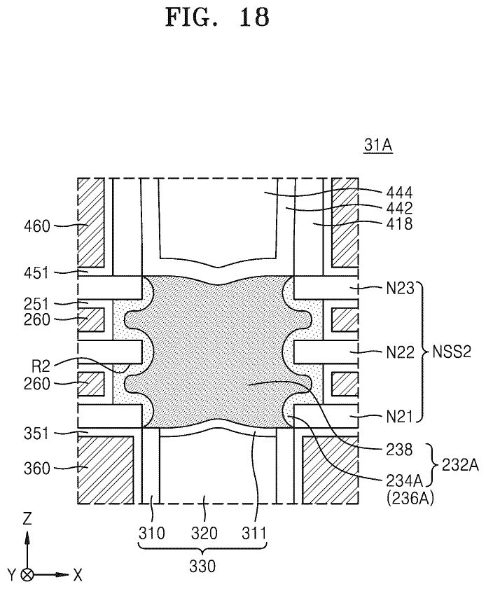

FIG. 18 is an enlarged cross-sectional view illustrating an integrated circuit device 31A according to some embodiments. For example, FIG. 18 is an enlarged cross-sectional view of a region corresponding to a region EX6 of FIG. 16. Hereinafter, to the extent that an element is not described in detail with respect to this figure, it may be understood that the element is at least similar to a corresponding element that has been described elsewhere within the present disclosure, for example, with respect to FIGS. 16 and 17.

Referring to FIG. 18, the integrated circuit device 31A may include an upper source/drain region 232A adjacent to the upper gate portion 260 and contacting the first upper nanosheet N21, the second upper nanosheet N22, and the third upper nanosheet N23 included in the upper nanosheet stack NSS2.

In some embodiments, the upper source/drain region 232A may include a first semiconductor pattern 234A and the third semiconductor pattern 238 covering the first semiconductor pattern 234A.

For example, the first semiconductor pattern 234A may contact side surfaces of each of the first upper nanosheet N21, the second upper nanosheet N22, and the third upper nanosheet N23, and integrally extend on side surfaces of each of the first upper nanosheet N21, the second upper nanosheet N22, and the third upper nanosheet N23 and side surfaces of the upper gate portion 260. The first semiconductor pattern 234A may include a part disposed between each of the first upper nanosheet N21, the second upper nanosheet N22, and the third upper nanosheet N23. For example, the first semiconductor pattern 234A may include a part disposed inside the second recess R2 between the first upper nanosheet N21 and the second upper nanosheet N22, and between the second upper nanosheet N22 and the third upper nanosheet N23. The third semiconductor pattern 238 may cover the first semiconductor pattern 234A and contact the first semiconductor pattern 234A.

In some embodiments, the upper source/drain region 232A may include a second semiconductor pattern 236A and the third semiconductor pattern 238 covering the second semiconductor pattern 236A.

For example, the second semiconductor pattern 236A may contact the side surfaces of each of the first upper nanosheet N21, the second upper nanosheet N22, and the third upper nanosheet N23, and integrally extend on the side surfaces of each of the first upper nanosheet N21, the second upper nanosheet N22, and the third upper nanosheet N23 and the side surfaces of the upper gate portion 260. The second semiconductor pattern 236A may include a part disposed between each of the first upper nanosheet N21, the second upper nanosheet N22, and the third upper nanosheet N23. For example, the second semiconductor pattern 236A may include a part disposed inside the second recess R2 between the first upper nanosheet N21 and the second upper nanosheet N22, and between the second upper nanosheet N22 and the third upper nanosheet N23. The third semiconductor pattern 238 may cover the second semiconductor pattern 236A and contact the second semiconductor pattern 236A.

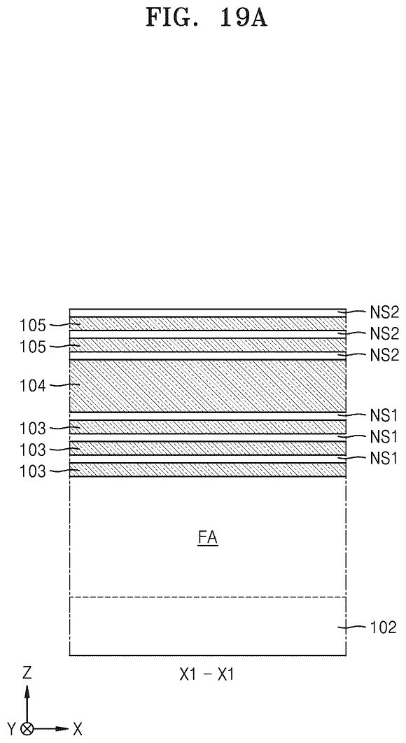

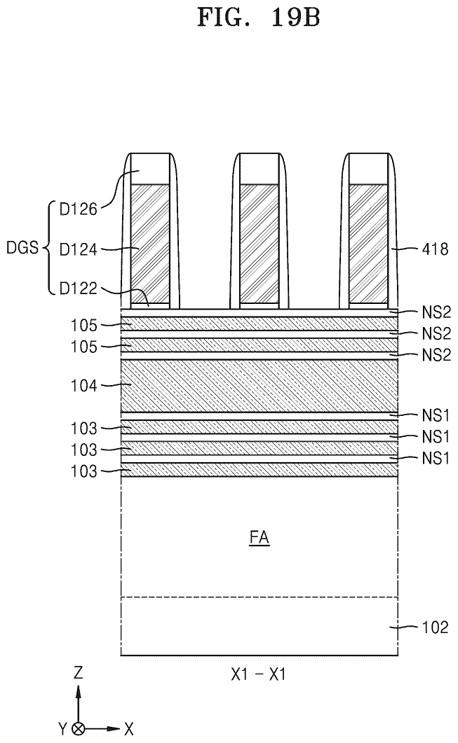

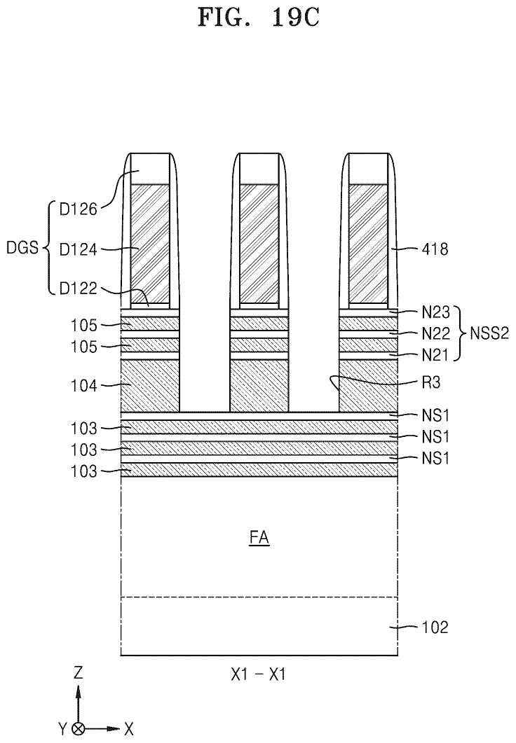

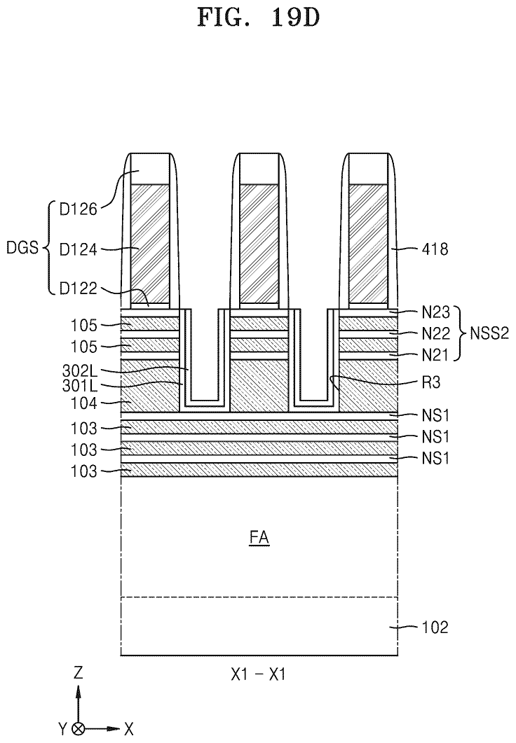

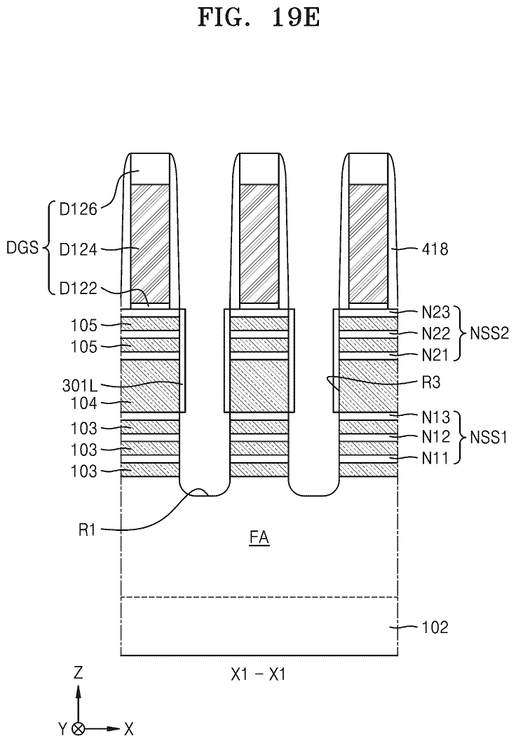

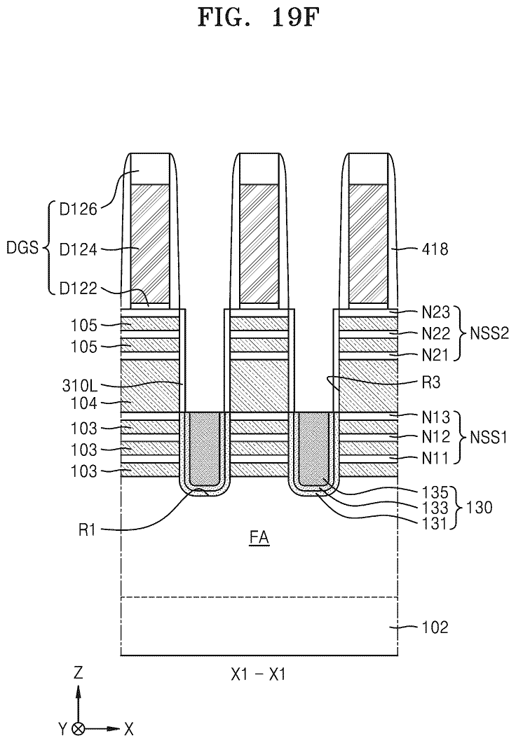

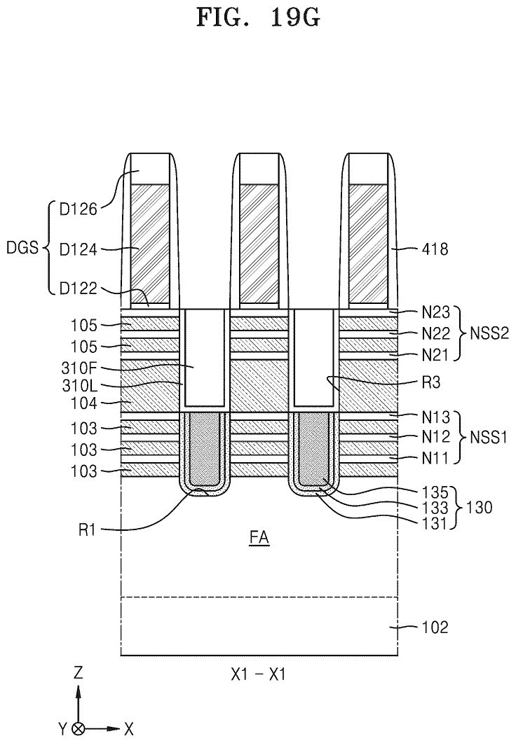

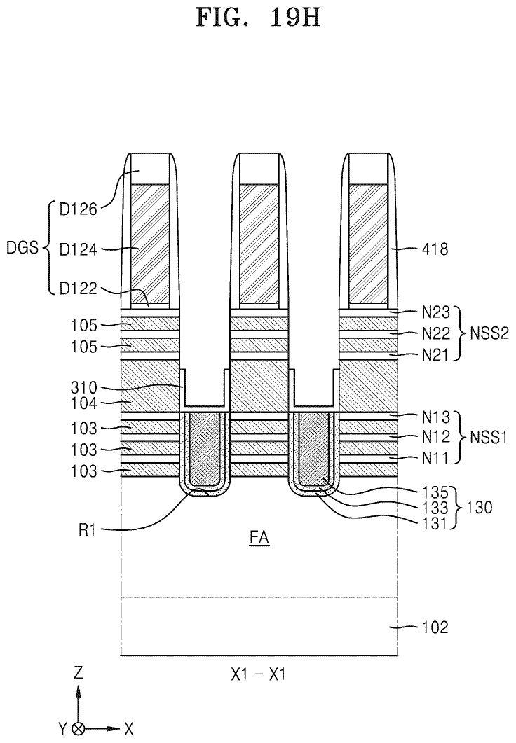

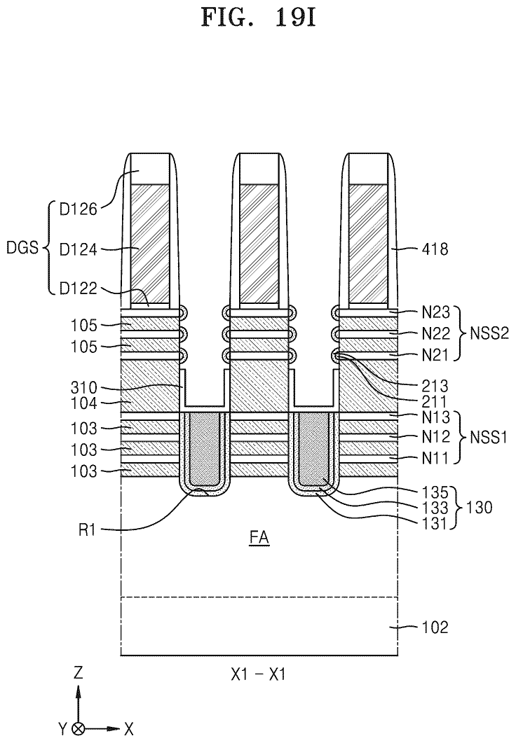

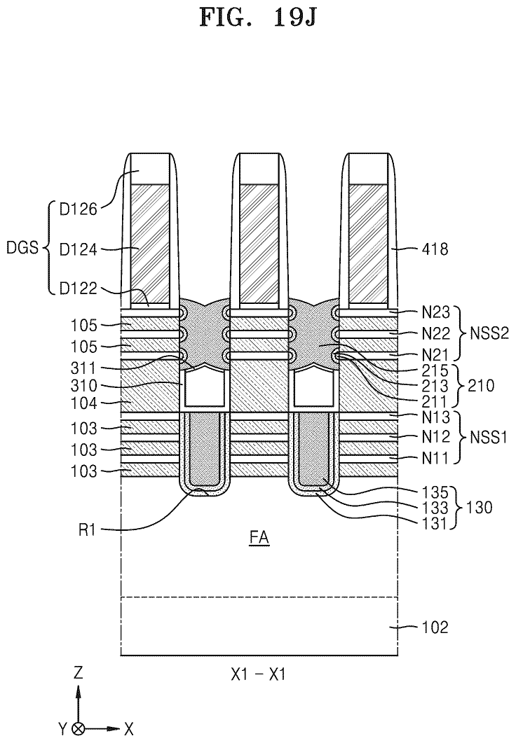

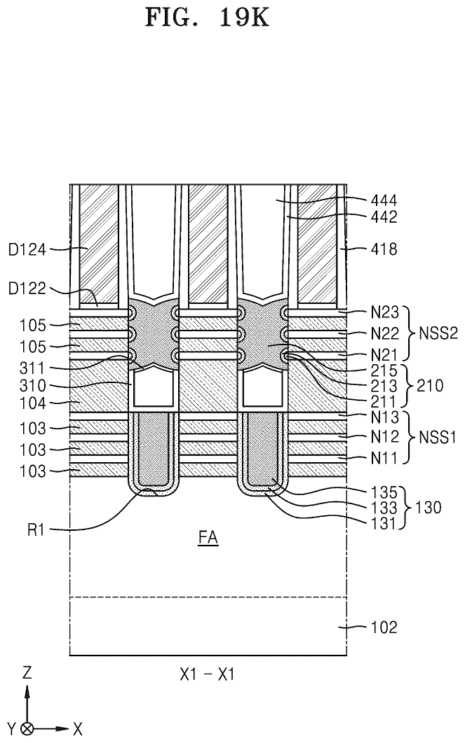

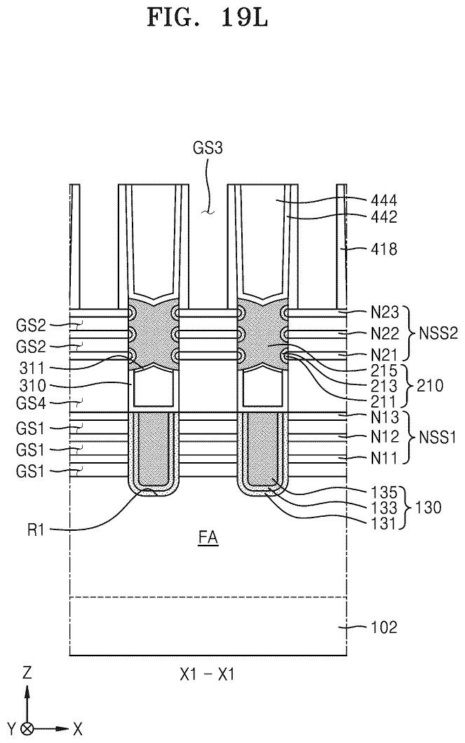

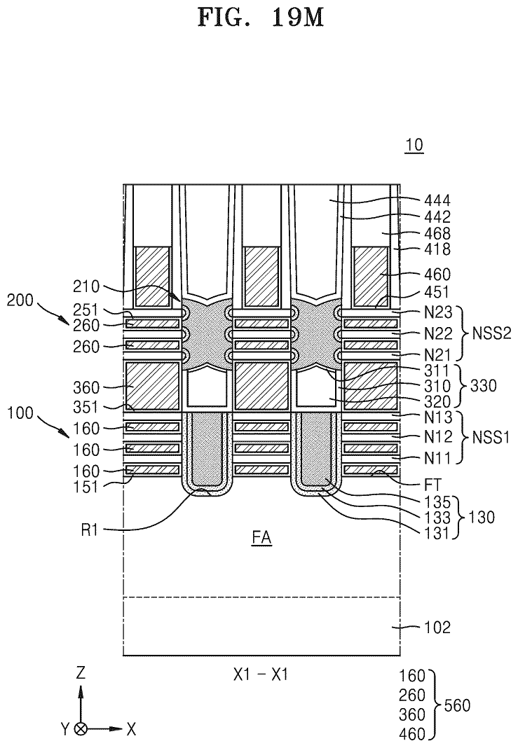

FIGS. 19A to 19M are cross-sectional views illustrating a method of manufacturing the integrated circuit device 10 according to some embodiments based on a process sequence. For example, FIGS. 19A to 19M are cross-sectional views corresponding to a cross-section taken along line X1-X1 of FIG. 1.

Referring to FIG. 19A, a plurality of lower, intermediate, and upper sacrificial semiconductor layers 103, 104, and 105 and a plurality of lower and upper nanosheet semiconductor layers NS1 and NS2 may be alternately stacked one by one on the substrate 102. The plurality of lower, intermediate, and upper sacrificial semiconductor layers 103, 104, and 105 may include a plurality of lower sacrificial semiconductor layers 103, a plurality of intermediate sacrificial semiconductor layers 104, and a plurality of upper sacrificial semiconductor layers 105. The plurality of lower and upper nanosheet semiconductor layers NS1 and NS2 may include a plurality of lower nanosheet semiconductor layers NS1 and a plurality of upper nanosheet semiconductor layers NS2. The plurality of lower, intermediate, and upper sacrificial semiconductor layers 103, 104, and 105 and the plurality of lower and upper nanosheet semiconductor layers NS1 and NS2 may include semiconductor materials having different etch selectivities.

For example, a thickness of each of the plurality of lower, intermediate, and upper sacrificial semiconductor layers 103, 104, and 105 in the vertical direction (e.g., Z direction) might not be constant, and the thickness of the intermediate sacrificial semiconductor layer 104 in the vertical direction (e.g., Z direction) may be greater than the thickness of each of the plurality of lower sacrificial semiconductor layers 103 and the plurality of upper sacrificial semiconductor layers 105 in the vertical direction (e.g., Z direction).

Thereafter, the plurality of fin-shaped active regions FA extending in the first horizontal direction (e.g., X direction) may be formed on the substrate 102 by etching the lower, intermediate, and upper sacrificial semiconductor layers 103, 104, and 105, the plurality of lower and upper nanosheet semiconductor layers NS1 and NS2, and a part of the substrate 102. As a result, the plurality of fin-shaped active regions FA may be disposed on the substrate 102. A stack structure of the plurality of lower, intermediate, and upper sacrificial semiconductor layers 103, 104, and 105 and the plurality of lower and upper nanosheet semiconductor layers NS1 and NS2 may remain on a fin top surface of each of the plurality of fin-type active regions FA.

Referring to FIG. 19B, a plurality of dummy gate structures DGS may be formed on the stack structure of the plurality of lower, intermediate, and upper sacrificial semiconductor layers 103, 104, and 105 and the plurality of lower and upper nanosheet semiconductor layers NS1 and NS2.

Each of the plurality of dummy gate structures DGS may extend primarily in the second horizontal direction (e.g., Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon, and the capping layer D126 may include a silicon nitride layer.

Referring to FIG. 19C, a plurality of outer insulating spacers 418 covering both sidewalls of each of the plurality of dummy gate structures DGS may be formed, and then, some of the plurality of lower, intermediate, and upper sacrificial semiconductor layers 103, 104, and 105 and some of the plurality of lower and upper nanosheet semiconductor layers NS1 and NS2 may be etched by using the plurality of dummy gate structures DGS and the plurality of outer insulating spacers 418 as an etch mask. For example, some of the plurality of upper sacrificial semiconductor layers 105 and the intermediate sacrificial semiconductor layer 104 may be etched, and some of the plurality of upper nanosheet semiconductor layers NS2 may be etched.

Accordingly, the plurality of upper nanosheet semiconductor layers NS2 may be respectively divided into the plurality of upper nanosheet stacks NSS2 each including the first upper nanosheet N21, the second upper nanosheet N22, and the third upper nanosheet N23.

Through an etching process, a plurality of third recesses R3 may be formed. The plurality of upper sacrificial semiconductor layers 105, the intermediate sacrificial semiconductor layer 104, and the plurality of upper nanosheet stacks NSS2 may be exposed by the plurality of third recesses R3. To form the plurality of third recesses R3, etching may be performed using dry etching, wet etching, or a combination thereof.

Referring to FIG. 19D, a first insulating layer 301L and a second insulating layer 302L may be formed on inner walls and bottom surfaces of the plurality of third recesses R3. The first insulating layer 301L may be used to protect the first upper nanosheet N21, the second upper nanosheet N22, and the third upper nanosheet N23 in a subsequent etching process. The first insulating layer 301L may include nitride. The second insulating layer 302L may include oxide.

Referring to FIG. 19E, the first recess RI may be formed by etching some of the plurality of lower sacrificial semiconductor layers 103 and some of the plurality of lower nanosheet semiconductor layers NS1. Forming the first recess RI may include widening a recess by etching some of the plurality of lower sacrificial semiconductor layers 103 and some of the plurality of lower nanosheet semiconductor layers NS1 by using the first insulating layer 301L as an etch mask and then performing an etching process in a horizontal direction. As a result, the second insulating layer 302L may be removed. The plurality of lower nanosheet semiconductor layers NS1 may be respectively divided into the plurality of lower nanosheet stacks NSS1 each including the first lower nanosheet N11, the second lower nanosheet N12, and the third lower nanosheet N13.

Referring to FIG. 19F, the plurality of lower source/drain regions 130 may be respectively formed inside the plurality of first recesses R1. In some embodiments, in order to form the plurality of lower source/drain regions 130, a semiconductor material may epitaxially grow from a surface of the fin-shaped active region FA exposed from a bottom surface of the recess, sidewalls of each of the first lower nanosheet N11, the second lower nanosheet N12, and the third lower nanosheet N13 included in the lower nanosheet stack NSS1, and sidewalls of each of the plurality of lower sacrificial semiconductor layers 103.

Referring to FIG. 19G, a first insulating layer 310L including nitride may be formed inside the third recess R3 and then, a first filling layer 310F may be formed on the first insulating layer 310L. The first insulating layer 310L may be formed by applying an insulating material including nitride on the remaining first insulating layer 310L in a process of FIG. 19E. The first filling layer 310F may include oxide.

Referring to FIG. 19H, the insulating spacer 310 may be formed by etching the first insulating layer 310L and the first filling layer 310F.

For example, an upper portion of the first filling layer 310F may be removed and then, a part of the first insulating layer 310L exposed by removing the upper portion of the first filling layer 310F may be removed. Thereafter, a lower portion of the first filling layer 310F may be completely removed by performing a preprocessing process. Removing the part of the first insulating layer 310L may use a wet etching process.

The preprocessing process may include cleaning exposed side surfaces of the plurality of upper sacrificial semiconductor layers 105 and side surfaces of the first upper nanosheet N21, the second upper nanosheet N22, and the third upper nanosheet N23 by using hydrogen fluoride (HF).

Referring to FIG. 191, the first semiconductor pattern 211 may be formed on the side surfaces of the first upper nanosheet N21, the second upper nanosheet N22, and the third upper nanosheet N23, and the second semiconductor pattern 213 may be formed on the first semiconductor pattern 211.

For example, the first semiconductor pattern 211 may be formed by epitaxially growing a semiconductor material on the side surfaces of the first upper nanosheet N21, the second upper nanosheet N22, and the third upper nanosheet N23. In this regard, when the preprocessing process is performed, the semiconductor material does not grow on the side surfaces of the plurality of upper sacrificial semiconductor layers 105, so that the first semiconductor pattern 211 may have a shape protruding from the side surfaces of each of the first upper nanosheet N21, the second upper nanosheet N22, and the third upper nanosheet N23.

Next, the second semiconductor pattern 213 may be formed by epitaxially growing the semiconductor material on the first semiconductor pattern 211.

Referring to FIG. 19J, the third semiconductor pattern 215 may cover the first semiconductor pattern 211 and the second semiconductor pattern 213.

For example, the upper source/drain region 210 may be formed by epitaxially growing a semiconductor material on the second semiconductor pattern 213 and forming the third semiconductor pattern 215 filled between a pair of upper nanosheet stacks NSS2 and between a pair of upper gate portions 260.

In this regard, the third semiconductor pattern 215 may grow on the first semiconductor pattern 211 and the second semiconductor pattern 213 each having the shape protruding from the side surfaces of each of the first upper nanosheet N21, the second upper nanosheet N22, and the third upper nanosheet N23, so that a top surface and a lower surface of the third semiconductor pattern 215 may each have an irregular vertical level. For example, a vertical level of a part of the lower surface of the third semiconductor pattern 215 that overlaps the first semiconductor pattern 211 and the second semiconductor pattern 213 in the vertical direction (e.g., Z direction) may be lower than a vertical level of a part that does not overlap the first semiconductor pattern 211 and the second semiconductor pattern 213 in the vertical direction (e.g., Z direction). Likewise, a vertical level of a part of the top surface of the third semiconductor pattern 215 that overlaps the first semiconductor pattern 211 and the second semiconductor pattern 213 in the vertical direction (e.g., Z direction) may be higher than a vertical level of a part that does not overlap the first semiconductor pattern 211 and the second semiconductor pattern 213 in the vertical direction (e.g., Z direction).

Subsequently, the isolation insulating layer 311 may cover a lower surface of the upper source/drain region 210.

Referring to FIG. 19K, a top surface of the capping layer D126 may be exposed by forming the insulating liner 442 that covers a resultant of FIG. 19J in which the plurality of upper source/drain regions 210 are formed, forming the inter-gate insulating layer 444 on the insulating liner 442, and then planarizing the insulating liner 442 and the inter-gate insulating layer 444.

Thereafter, a top surface of the dummy gate layer D124 may be exposed by removing the capping layer D126, and the insulating liner 442 and the inter-gate insulating layer 444 may be partially removed so that a top surface of the inter-gate insulating layer 444 and the top surface of the dummy gate layer D124 may be approximately at the same level.

Referring to FIG. 19L, a third gate space GS3 may be prepared by removing the dummy gate layer D124 and the oxide layer D122 therebelow, and the plurality of upper nanosheet stacks NSS2 may be exposed through the third gate space GS3.

Subsequently, a first gate space GS1 between the first lower nanosheet N11, the second lower nanosheet N12, and the third lower nanosheet N13, a second gate space GS2 between the first upper nanosheet N21, the second upper nanosheet N22, and the third upper nanosheet N23, and a fourth gate space GS4 between the lower nanosheet stack NSS1 and the upper nanosheet stack NSS2 may be prepared by removing the plurality of lower, intermediate, and upper sacrificial semiconductor layers 103, 104, and 105 remaining on the fin-type active regions FA through the third gate space GS3.

In some embodiments, differences in etch selectivity between the plurality of nanosheets and the plurality of lower, intermediate, and upper sacrificial semiconductor layers 103, 104, and 105 may be used to selectively remove the plurality of lower, intermediate, and upper sacrificial semiconductor layers 103, 104, and 105.

Referring to FIG. 19M, the gate dielectric layers 151, 251, 351, and 451 may be respectively formed in the first to fourth gate spaces GS1 to GS4, the plurality of gates 560 may be formed on the gate dielectric layers 151, 251, 351, and 451, and the capping insulating pattern 468 may be formed on the plurality of gate lines 560. As a result, the integrated circuit device 10 described with reference to FIGS. 1 to 4 may be manufactured.

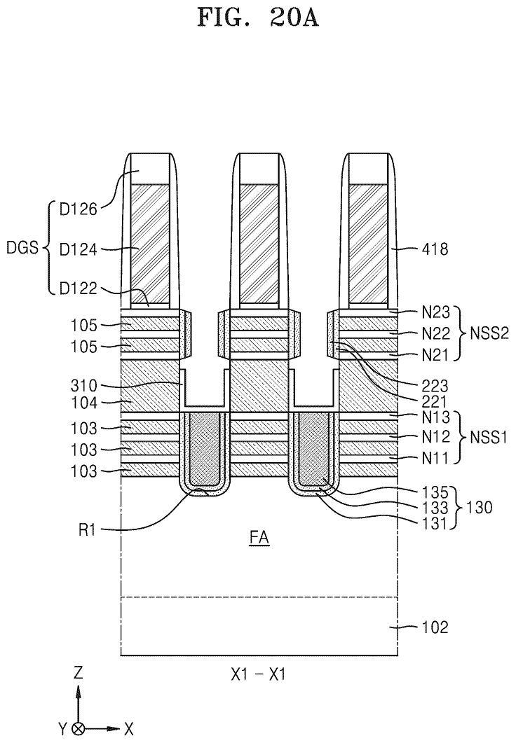

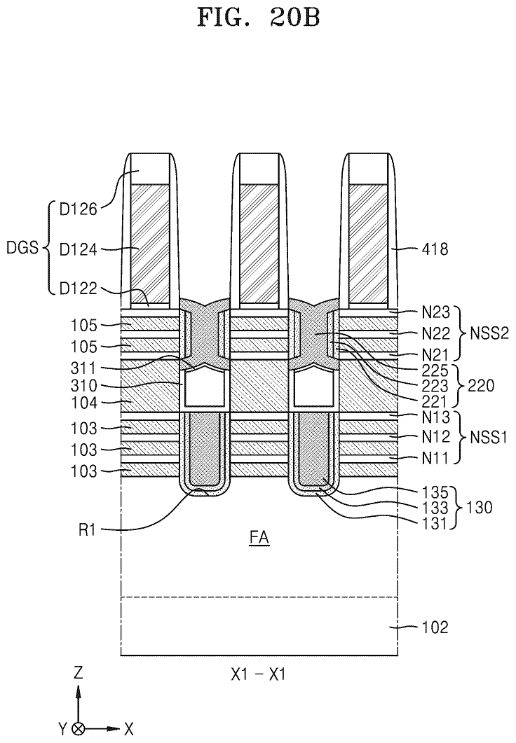

FIGS. 20A and 20B are intermediate cross-sectional views illustrating a method of manufacturing the integrated circuit device 20 according to some embodiments based on a process sequence. For example, FIGS. 20A and 20B are diagrams illustrating processes performed subsequent to FIG. 19H.

Referring to FIG. 20A, the first semiconductor pattern 221 may be formed on side surfaces of the first upper nanosheet N21, the second upper nanosheet N22, and the third upper nanosheet N23, and the second semiconductor pattern 223 may be formed on the first semiconductor pattern 221.

For example, the first semiconductor pattern 221 may be formed by epitaxially growing a semiconductor material on the side surfaces of the first upper nanosheet N21, the second upper nanosheet N22, and the third upper nanosheet N23 and side surfaces of the plurality of upper sacrificial semiconductor layers 105.

In this regard, when hydrogen fluoride (HF), pure ozone (Ozone-Di-ionized (O3-DI)), and Standard Clean 1 (SC1) cleaning solution are used during a preprocessing process, a semiconductor material may grow on the side surfaces of the first upper nanosheet N21, the second upper nanosheet N22, and the third upper nanosheet N23 as well as the side surfaces of the plurality of upper sacrificial semiconductor layers 105 to have a shape integrally extending on the side surfaces of each of the first upper nanosheet N21, the second upper nanosheet N22, and the third upper nanosheet N23 and side surfaces of the upper gate portion 260 (see FIGS. 7 and 8).

Next, the second semiconductor pattern 223 may be formed by epitaxially growing the semiconductor material on the first semiconductor pattern 221. For example, the second semiconductor pattern 223 may be formed by epitaxially growing the semiconductor material on the second surface 221_S2 (see FIG. 8) of the first semiconductor pattern 221. Meanwhile, an epitaxial growth rate of the semiconductor material is slow on the third surface 221_S3 (see FIG. 8) of the first semiconductor pattern 221, so that the second semiconductor pattern 223 may be hardly formed on the third surface 221_S3.

Referring to FIG. 20B, the third semiconductor pattern 225 may cover the first semiconductor pattern 221 and the second semiconductor pattern 223.

For example, the upper source/drain region 220 may be formed by epitaxially growing the semiconductor material on the second semiconductor pattern 223 and forming the third semiconductor pattern 225 filled between a pair of upper nanosheet stacks NSS2 and between a pair of upper gate portions 260.

Subsequently, the isolation insulating layer 311 may cover a lower surface of the upper source/drain region 220.

Subsequently, the integrated circuit device 20 described with reference to FIGS. 7 and 8 may be formed by performing subsequent processes similar to those described with reference to FIGS. 19K to 19M.

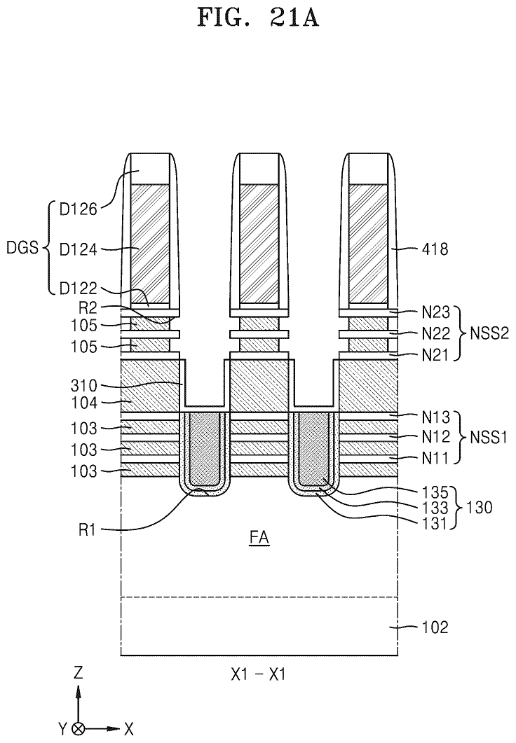

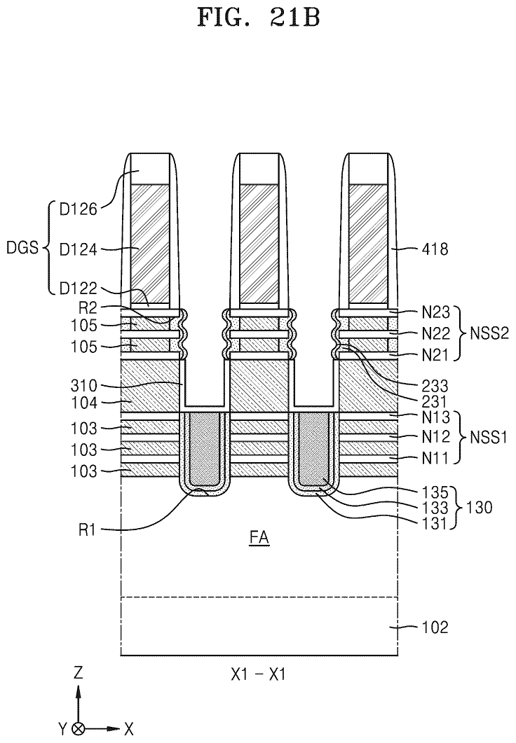

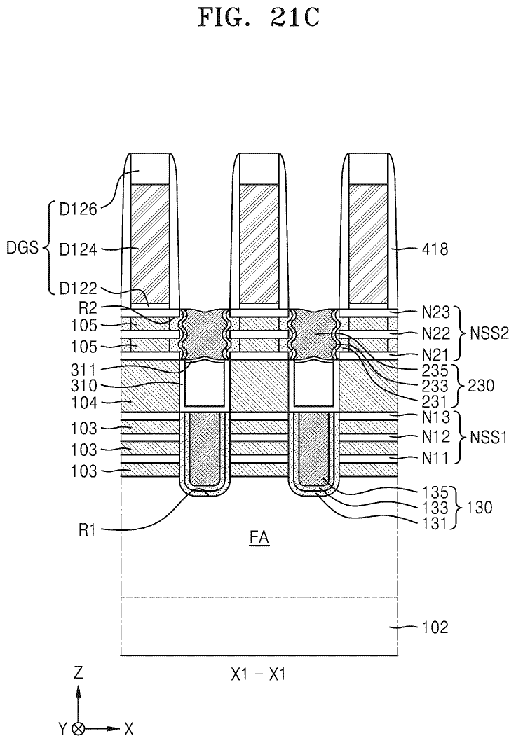

FIGS. 21A to 21C are intermediate cross-sectional views illustrating a method of manufacturing the integrated circuit device 30 according to some embodiments based on a process sequence. For example, FIGS. 21A to 21C are diagrams illustrating processes performed subsequent to FIG. 19H.

Referring to FIG. 21A, the plurality of second recesses R2 may be formed by etching some of the upper sacrificial semiconductor layer 105 exposed by the third recess R3 (see FIG. 19C).

Referring to FIG. 21B, the first semiconductor pattern 231 may be formed on side surfaces of the first upper nanosheet N21, the second upper nanosheet N22, and the third upper nanosheet N23, and the second semiconductor pattern 233 may be formed on the first semiconductor pattern 231.

For example, the first semiconductor pattern 231 may be formed by epitaxially growing a semiconductor material on the side surfaces of the first upper nanosheet N21, the second upper nanosheet N22, and the third upper nanosheet N23 and side surfaces of the plurality of upper sacrificial semiconductor layers 105 inside the second recess R2.

Next, the second semiconductor pattern 233 may be formed by epitaxially growing the semiconductor material on the first semiconductor pattern 231.

Referring to FIG. 21C, the third semiconductor pattern 235 may cover the first semiconductor pattern 231 and the second semiconductor pattern 233.

For example, the upper source/drain region 230 may be formed by epitaxially growing the semiconductor material on the second semiconductor pattern 233 and forming the third semiconductor pattern 235 filled between a pair of upper nanosheet stacks NSS2 and between a pair of upper gate portions 260.

Subsequently, the isolation insulating layer 311 may cover a lower surface of the upper source/drain region 230.

Subsequently, the integrated circuit device 30 described with reference to FIGS. 13 and 14 may be formed by performing subsequent processes similar to those described with reference to FIGS. 19K to 19M.

While the inventive concept has been particularly shown and described with reference to embodiments thereof, it will be understood that various changes in form and details may be made therein without departing from the spirit and scope of the present disclosure.

What is claimed is:

1. An integrated circuit device, comprising:
a fin-shaped active region extending in a first horizontal direction on a substrate;
a pair of lower channel regions disposed on the fin-shaped active region and spaced apart from one another in the first horizontal direction;
a pair of upper channel regions disposed on upper portions of the pair of lower channel regions and spaced apart from one another in the first horizontal direction;
a gate line disposed on the fin-shaped active region and comprising a pair of lower gate portions surrounding the pair of lower channel regions and extending in a second horizontal direction intersecting the first horizontal direction, and a pair of upper gate portions surrounding the pair of upper channel regions and extending in the second horizontal direction;
a lower source/drain region disposed on the fin-shaped active region, adjacent to the pair of lower gate portions, and contacting the pair of lower channel regions;
an upper source/drain region disposed on the lower source/drain region, adjacent to the pair of upper gate portions, and contacting the pair of upper channel regions; and
an isolation structure disposed between the lower source/drain region and the upper source/drain region,
wherein the upper source/drain region comprises a first semiconductor pattern contacting side surfaces of the pair of upper channel regions, a second semiconductor pattern covering the first semiconductor pattern, and a third semiconductor pattern filled between the pair of upper gate portions, and covering the first semiconductor pattern and the second semiconductor pattern, and
wherein a lowermost portion of a lower surface of the upper source/drain region is a part of a lower surface of the third semiconductor pattern.

2. The integrated circuit device of claim 1:
wherein the first semiconductor pattern comprises a silicon (Si) layer,
wherein the second semiconductor pattern comprises a silicon (Si) layer including a first dopant,
wherein the third semiconductor pattern comprises a silicon (Si) layer including a second dopant,
wherein a concentration of the first dopant in the second semiconductor pattern is lower than a concentration of the second dopant in the third semiconductor pattern, and
wherein the first dopant and the second dopant comprise n-type dopants.

3. The integrated circuit device of claim 1:
wherein the lower source/drain region includes a Si1−xGex layer doped with a p-type dopant (where x≠0), and includes a plurality of lower semiconductor patterns having different concentrations of the p-type dopant, and
wherein the plurality of lower semiconductor patterns include a U-shaped outer layer on an inner wall of a recess between the pair of lower gate portions and an inner layer completely filled in the recess on the outer layer.

4. The integrated circuit device of claim 1, wherein the third semiconductor pattern includes a part that overlaps the first semiconductor pattern and the second semiconductor pattern in a vertical direction, between the first semiconductor pattern and the isolation structure.

5. The integrated circuit device of claim 1, wherein the third semiconductor pattern contacts both the first semiconductor pattern and the second semiconductor pattern.

6. The integrated circuit device of claim 1, wherein the third semiconductor pattern includes a part that does not overlap either the first semiconductor pattern or the second semiconductor pattern in a vertical direction.

7. The integrated circuit device of claim 1, wherein a lowermost portion of a top surface and an uppermost portion of the lower surface of the upper source/drain region do not overlap either the first semiconductor pattern or the second semiconductor pattern in a vertical direction.

8. The integrated circuit device of claim 1, wherein the third semiconductor pattern directly contacts the isolation structure.

9. The integrated circuit device of claim 1:
wherein the first semiconductor pattern includes a first part that overlaps the upper channel region in the first horizontal direction and a second part that does not overlap the upper channel region in the first horizontal direction, and
wherein a thickness of the first part in the first horizontal direction is less than a thickness of the second part in the first horizontal direction.

10. An integrated circuit device, comprising:
a fin-shaped active region extending in a first horizontal direction on a substrate;
a lower stack comprising a lower source/drain region disposed on the fin-shaped active region;
an upper stack disposed on an upper portion of the lower stack and comprising an upper nanosheet stack comprising a plurality of upper nanosheets stacked in a vertical direction, an upper gate portion disposed between each of the plurality of upper nanosheets and extending in a second horizontal direction intersecting the first horizontal direction, and an upper source/drain region adjacent to the upper gate portion and contacting the plurality of upper nanosheets; and
an isolation structure contacting each of the lower source/drain region and the upper source/drain region, between the lower stack and the upper stack,
wherein the upper source/drain region comprises a first semiconductor pattern contacting side surfaces of the plurality of upper nanosheets, and a second semiconductor pattern covering the first semiconductor pattern, and
wherein an uppermost portion of a lower surface of the upper source/drain region is a part of a lower surface of the second semiconductor pattern.

11. The integrated circuit device of claim 10, wherein the lower stack further includes:
a lower nanosheet stack including a plurality of lower nanosheets stacked in the vertical direction; and
a lower gate portion disposed between each of the plurality of lower nanosheets and between a lowermost lower nanosheet among the plurality of lower nanosheets and the fin-shaped active region, and extending in the second horizontal direction,
wherein the lower source/drain region is adjacent to the lower gate portion and contacts the plurality of lower nanosheets.

12. The integrated circuit device of claim 10, wherein the second semiconductor pattern directly contacts the first semiconductor pattern.

13. The integrated circuit device of claim 10:
wherein the upper source/drain region further includes a third semiconductor pattern disposed between the first semiconductor pattern and the second semiconductor pattern, and
wherein the second semiconductor pattern contacts the third semiconductor pattern and does not contact the first semiconductor pattern.

14. The integrated circuit device of claim 10, wherein the first semiconductor pattern integrally extends on side surfaces of each of the plurality of upper nanosheets and side surfaces of the upper gate portion.

15. The integrated circuit device of claim 10, wherein the first semiconductor pattern includes a part disposed between each of the plurality of upper nanosheets.

16. The integrated circuit device of claim 10:
wherein the plurality of upper nanosheets include a first upper nanosheet and a second upper nanosheet stacked in the vertical direction,
wherein the first semiconductor pattern includes a first island region protruding from side surfaces of the first upper nanosheet and a second island region protruding from side surfaces of the second upper nanosheet, and
wherein the first island region and the second island region are separated from each other in the vertical direction.

17. The integrated circuit device of claim 16, wherein the second semiconductor pattern is disposed between the first island region and the second island region, and includes a part that overlaps the first island region and the second island region in the vertical direction.

18. An integrated circuit device, comprising:
a fin-shaped active region extending in a first horizontal direction on a substrate;
a lower stack disposed on the fin-shaped active region;
an isolation structure disposed on the lower stack; and
an upper stack disposed on the isolation structure,
wherein the lower stack comprises:
a pair of lower channel regions disposed on the fin-shaped active region and spaced apart in the first horizontal direction;
a pair of lower gate portions respectively surrounding the pair of lower channel regions and extending in a second horizontal direction intersecting the first horizontal direction; and
a lower source/drain region adjacent to the pair of lower gate portions, disposed between the pair of lower channel regions, and contacting the pair of lower channel regions,
wherein the upper stack comprises:
a pair of upper channel regions spaced apart from one another in the first horizontal direction;
a pair of upper gate portions respectively surrounding the pair of upper channel regions and extending in the second horizontal direction; and
an upper source/drain region adjacent to the pair of upper gate portions, disposed between the pair of upper channel regions, and contacting the pair of upper channel regions,
wherein the isolation structure contacts the lower source/drain region and the upper source/drain region,
wherein the upper source/drain region comprises a first semiconductor pattern contacting side surfaces of the pair of upper channel regions, a second semiconductor pattern covering the first semiconductor pattern, and third semiconductor pattern filled between the pair of upper channel regions, and covering the first semiconductor pattern and the second semiconductor pattern,
wherein the third semiconductor pattern contacts the isolation structure,
wherein at least a part of a lower surface of the upper source/drain region is a part of a lower surface of the third semiconductor pattern, and
wherein the lower stack comprises a p-channel metal-oxide-semiconductor (PMOS) device, and the upper stack comprises an n-channel metal-oxide-semiconductor (NMOS) device.

19. The integrated circuit device of claim 18:
wherein the first semiconductor pattern comprises a silicon (Si) layer,
wherein the second semiconductor pattern comprises a silicon (Si) layer including a first dopant,
wherein the third semiconductor pattern comprises a silicon (Si) layer including a second dopant,
wherein a concentration of the first dopant in the second semiconductor pattern is lower than a concentration of the second dopant in the third semiconductor pattern,
wherein the first dopant and the second dopant each include arsenic (As), phosphorus (P), and/or carbon (C), and
wherein the lower source/drain region includes a Si1−xGex layer doped with a p-type dopant (where x≠0), and includes a plurality of lower semiconductor patterns having different concentrations of the p-type dopant.

20. The integrated circuit device of claim 18, wherein the isolation structure includes:
an isolation insulating layer contacting the lower source/drain region and the upper source/drain region and including nitride;
an air gap surrounded by the isolation insulating layer, and
the isolation insulating layer contacts the third semiconductor pattern.
